(19) United States
(12) Patent Application Publication
(10) Pub. No.: US 2013/0149464 A1
(43) Pub. Date: Jun. 13, 2013

(54) METHOD OF MANUFACTURING CIRCUIT BOARD

(71) Applicant: Sony Corporation, Tokyo (JP)

(72) Inventors: Shinji Rokuhara, Kanagawa (JP); Kiwamu Adachi, Kanagawa (JP); Shuichi Oka, Kanagawa (JP); Katsuji Matsumoto, Kanagawa (JP); Shusaku Yanagawa, Kanagawa (JP); Satoshi Horiuchi, Kanagawa (JP)

(73) Assignee: SONY CORPORATION, Tokyo (JP)

(21) Appl. No.: 13/686,479

(22) Filed: Nov. 27, 2012

(30) Foreign Application Priority Data
Dec. 12, 2011 (JP) 2011-271194

(51) Int. Cl. H05K 3/02

(52) U.S. Cl. CPC H05K 3/02
USPC 427/554; 427/79

(57) ABSTRACT

A method of manufacturing a circuit board, the method includes: forming a capacitive device and a short-circuit section with use of a capacitive device material including a dielectric film and a conductive film in this order on metallic foil, the capacitive device including a first electrode layer and a second electrode layer with the dielectric film interposed therebetween, and the short-circuit section short-circuiting the first electrode layer and the second electrode layer; forming an upper-layer wiring above the capacitive device and the short-circuit section; and removing or cutting the short-circuit section after the forming of the upper-layer wiring.

### BACKGROUND

The disclosure relates to a method of manufacturing a circuit board, and particularly, to a method of manufacturing a circuit board incorporating a capacitive device.

A capacitive device has been formed in a circuit board (a mounted substrate) such as a printed circuit board (see, for example, Japanese Unexamined Patent Application Publication No. 2007-12667).

In order to achieve a high capacitance value while downsizing the capacitive device, it is effective to reduce the thickness of a dielectric film and adopt a dielectric material with a high dielectric constant.

As a way of forming such a thin dielectric film in the mounted substrate, a film formation technique such as a sol-gel process, an aerosol method, and sputtering may be used, and the development of adaptation thereof has been pursued.

In addition, in order to reduce the thickness of the dielectric film of the capacitive device, it is necessary to have high pressure-resistance with a low leakage current. For this reason, it is desired that materials such as impurities due to the film formation material of the dielectric film do not remain in the film. These impurities reduce the dielectric constant, and from this viewpoint, it is desirable that the impurities do not stay in the film either. In order to suppress remaining of the impurities, it is preferable to form the film at a high temperature.

As the dielectric material having a high dielectric constant, crystalline dielectric materials such as strontium titanate (SrTiO₃: STO), barium titanate (BaTiO₃: BTO), barium strontium titanate (BST), and lead zirconate titanate (PZT) are known. The dielectric constant of such a crystalline dielectric material depends on its crystallinity, and therefore, it is desirable to form a film thereof at a higher temperature, so as to achieve a high dielectric constant.

Meanwhile, among materials used to form the mounted substrate, those with upper temperature limit of about 200° C. have been widely used. It is difficult to form a dielectric film at a high temperature, on the mounted substrate made of these materials.

In recent years, attention has been given to a manufacturing method that achieves formation of a dielectric film at a high temperature. In this method, a thin-film capacitive device material, in which a dielectric film is formed on metallic foil and a conductive film is further formed thereon, is adhered to the inside of a mounted substrate, instead of performing film formation on the mounted substrate.

### SUMMARY

A thin-film capacitive device material, in which a dielectric film is formed on a metallic foil and a conductive film is formed further thereon, has a structure in which the metallic foil under the dielectric film and the conductive film on the dielectric film are short-circuited in an outer peripheral portion. This is to prevent destruction (electrostatic destruction) resulting from static electricity generated in a process such as handling. However, effects of this measure against electrostatic destruction are lost at the time when the films such as metallic foil and the conductive film is disconnected or processed to form an electrode. In addition, since the dielectric film of the capacitive device to be incorporated into the mounted substrate is thin, there has been a concern about electrostatic destruction in a process of forming the capacitive device.

It is desirable to provide a method of manufacturing a circuit board capable of suppressing electrostatic destruction of a dielectric film.

According to an embodiment of the disclosure, there is provided a method of manufacturing a circuit board, the method including: forming a capacitive device and a short-circuit section with use of a capacitive device material including a dielectric film and a conductive film in this order on metallic foil, the capacitive device including a first electrode layer and a second electrode layer with the dielectric film interposed therebetween, and the short-circuit section short-circuiting the first electrode layer and the second electrode layer; forming an upper-layer wiring above the capacitive device and the short-circuit section; and removing or cutting the short-circuit section after the forming of the upper-layer wiring.

According to the method of manufacturing a circuit board in the embodiment of the disclosure, the capacitive device and the short-circuit section are formed using the capacitive device material having the dielectric film and the conductive film in this order on the metallic foil. The capacitive device has the first electrode layer and the second electrode layer with the conductive film interposed therebetween, and the short-circuit section short-circuits the first electrode layer and the second electrode layer. Then, after the upper-layer wiring is formed above the capacitive device and the short-circuit section, the short-circuit section is removed or cut. Therefore, electrostatic destruction of the dielectric film is suppressed by the short-circuit section, even after the first electrode layer and the second electrode layer are formed by cutting or processing the metallic foil and the conductive film.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to describe the principles of the technology.

Part (A) and Part (B) of FIG. 1 are a cross-sectional view and a plan view, respectively, of a configuration of a capacitive device in a circuit board according to a first embodiment of the disclosure.

FIGS. 2A to 2C are cross-sectional diagrams illustrating a method of manufacturing a circuit board depicted in Part (A) and Part (B) of FIG. 1, in process order.

FIG. 3 is a plan view illustrating a configuration of a second electrode layer depicted in FIG. 2C.

FIGS. 4A and 4B are cross-sectional diagrams illustrating processes following FIG. 2C.

FIGS. 5A to 5C are cross-sectional diagrams illustrating processes following FIG. 4B.

FIGS. 6A and 6B are cross-sectional diagrams illustrating processes following FIG. 5C.

FIG. 7 is a plan view illustrating a configuration of a first electrode layer and a short-circuit section depicted in FIG. 6B.

FIGS. 8A to 8C are cross-sectional diagrams illustrating processes following FIG. 6B.

FIGS. 9A to 9C are cross-sectional diagrams illustrating processes following FIG. 8C.

FIGS. 10A to 10C are cross-sectional diagrams illustrating a method of manufacturing a circuit board according to a second embodiment of the disclosure, in process order.

FIG. 11 is a plan view illustrating a configuration of a second electrode layer depicted in FIG. 10C.

FIGS. 12A and 12B are cross-sectional diagrams illustrating processes following FIG. 10C.

FIGS. 13A to 13C are cross-sectional diagrams illustrating processes following FIG. 12B.

FIG. 14 is a plan view illustrating a configuration of a first electrode layer and a short-circuit section depicted in FIG. 13B.

FIGS. 15A to 15C are cross-sectional diagrams illustrating processes following FIG. 13C.

FIGS. 16A to 16C are cross-sectional diagrams illustrating processes following FIG. 15C.

FIGS. 17A to 17E are cross-sectional diagrams illustrating a method of manufacturing a circuit board according to a third embodiment of the disclosure, in process order.

FIG. 18 is a plan view illustrating a configuration of a second electrode layer depicted in FIG. 17E.

FIGS. 19A to 19D are cross-sectional diagrams illustrating processes following FIG. 17E.

FIG. 20 is a plan view illustrating a configuration of a first electrode layer and a short-circuit section depicted in FIG. 19D.

FIGS. 21A to 21C are cross-sectional diagrams illustrating processes following FIG. 19D.

FIGS. 22A to 22C are cross-sectional diagrams illustrating processes following FIG. 21C.

Part (A) and Part (B) of FIG. 23 are a cross-sectional view and a plan view, respectively, of a configuration of a capacitive device in a circuit board according to a fourth embodiment of the disclosure.

FIGS. 24A to 24E are cross-sectional diagrams illustrating a method of manufacturing the circuit board depicted in Part (A) and Part (B) of FIG. 23, in process order.

FIG. 25 is a plan view illustrating a configuration of a second electrode layer having a short-circuit section depicted in FIG. 24E.

FIGS. 26A to 26D are cross-sectional diagrams illustrating processes following FIG. 25.

FIG. 27 is a plan view illustrating a configuration of a first electrode layer having the short-circuit section depicted in FIG. 26D.

FIGS. 28A to 28C are cross-sectional diagrams illustrating processes following FIG. 26D.

FIGS. 29A and 29B are cross-sectional diagrams illustrating processes following FIG. 28C.

FIGS. 30A and 30B are cross-sectional diagrams illustrating processes following FIG. 29B.

FIGS. 31A and 31B are cross-sectional diagrams each illustrating a configuration of a capacitive device of a circuit board according to a fifth embodiment of the disclosure.

FIGS. 32A and 32B are plan views of a configuration of the capacitive device depicted in FIGS. 31A and 31B.

FIGS. 33A to 33E are cross-sectional diagrams illustrating a method of manufacturing the circuit board depicted in FIGS. 31A and 31B, in process order.

FIG. 34 is a plan view illustrating a configuration of a second electrode layer of a first capacitive device and a first electrode layer of a second capacitive device depicted in FIG. 33E.

FIGS. 35A and 35B are cross-sectional diagrams illustrating processes following FIG. 34.

FIGS. 36A and 36B are cross-sectional diagrams illustrating a process following FIG. 35B.

FIGS. 37A and 37B are cross-sectional diagrams illustrating a process following FIGS. 36A and 36B.

FIG. 38 is a plan view illustrating a configuration of a first electrode layer of the first capacitive device, a second electrode layer of the second capacitive device, and a short-circuit section depicted in FIG. 37B.

FIGS. 39A and 39B are cross-sectional diagrams illustrating a process following FIGS. 37A and 37B.

FIGS. 40A and 40B are cross-sectional diagrams illustrating a process following FIGS. 39A and 39B.

FIGS. 41A and 41B are cross-sectional diagrams illustrating a process following FIGS. 40A and 40B.

FIGS. 42A and 42B are cross-sectional diagrams illustrating a process following FIGS. 41A and 41B.

FIGS. 43A and 43B are cross-sectional diagrams illustrating a process following FIGS. 42A and 42B.

FIGS. 44A and 44B are cross-sectional diagrams illustrating a process following FIGS. 43A and 43B.

FIG. 45 is a cross-sectional diagram illustrating a configuration of a capacitive device of a circuit board according to a sixth embodiment of the disclosure.

FIGS. 46A to 46C are cross-sectional diagrams illustrating a method of manufacturing the circuit board depicted in FIG. 45, in process order.

FIGS. 47A to 47C are cross-sectional diagrams illustrating processes following FIG. 46C.

FIG. 48 is a cross-sectional diagram illustrating a process following FIG. 47C.

### DETAILED DESCRIPTION

Embodiments of the disclosure will be described below in detail with reference to the drawings. It is to be noted that the description will be provided in the following order.

1. First embodiment (an example in which a short-circuit electrode is formed in an opening section provided in a dielectric film, and there is formed a short-circuit section that short-circuits a first leading wiring extended from a first electrode layer and a second leading wiring extended from a second electrode layer, through this short-circuit electrode)
2. Second embodiment (an example in which a damaged section is formed in a dielectric film by laser irradiation, and there is formed a short-circuit section that short-circuits a first leading wiring extended from a first electrode layer and a second leading wiring extended from a second electrode layer, through this damaged section)
3. Third embodiment (an example in which a contact section between metallic foil and a conductive film is formed in an opening section provided in a dielectric film, and there is formed a short-circuit section that short-circuits a first leading wiring extended from a first electrode layer and a second leading wiring extended from a second electrode layer, through this contact section)
4. Fourth embodiment (an example in which a first leading wiring and a second leading wiring are not formed, and a short-circuit section is formed inside a first electrode layer and a second electrode layer)
5. Fifth embodiment (an example in which two capacitive devices opposite in polarity are formed)
6. Sixth embodiment (an example in which an exterior wiring short-circuit section that short-circuits a first electrode layer and a second electrode layer through an exterior wiring is formed, and the exterior wiring short-circuit section is removed or cut after mounting or packaging)

### First Embodiment

Part (A) and Part (B) of FIG. 1 illustrate a cross-sectional configuration and a plane configuration, respectively, of a circuit board according to a first embodiment of the disclosure. This circuit board 1 is used, for example, as a printed circuit board or the like with a capacitive device 10 built therein. The capacitive device 10 includes, for instance, a first electrode layer 12 of a first polarity (e.g., +) on a top surface of a dielectric film 11, and a second electrode layer 13 of a second polarity (e.g., −) on an undersurface of the dielectric film 11. The capacitive device 10 is surrounded by a rectangular frame section 14. Further, as a matter of course, the circuit board 1 is provided with a wiring (not illustrated) necessary for the capacitive device 10, separately.

In the following description and drawings, directions are assumed as follows. A lamination direction of the first electrode layer 12, the dielectric film 11, and the second electrode layer 13 (i.e. a up-down direction on a sheet surface of Part (A) of FIG. 1) is assumed to be a z direction. A lateral direction on the sheet surface of Part (A) of FIG. 1 is assumed to be an x direction. A direction orthogonal to the sheet surface of Part (A) of FIG. 1 is assumed to be a y direction.

The dielectric film 11 is not limited in particular in terms of material. However, it is desirable that the dielectric film 11 be configured using a crystalline dielectric film having a high dielectric constant. Examples of a material that configures this crystalline dielectric film include strontium titanate (SrTiO₃; STO), barium titanate (BaTiO₃; BTO), barium strontium titanate (BST), and lead zirconate titanate (PZT). One reason for this is that this type of material makes it possible to reduce the size of the capacitive device 10, and to obtain a high capacitance value.

The first electrode layer 12 is not limited in particular in terms of material. However, the first electrode layer 12 is, for example, a single-layer conductive film made of metal such as copper and nickel, or a laminated body including a plurality of conductive films made of a plurality of materials. The second electrode layer 13 is not limited in particular in terms of material, but is configured using, for example, metallic foil made of metal such as copper and nickel. As illustrated in Part (B) of FIG. 1, the second electrode layer 13 is longer than the first electrode layer 12 in the x direction, in view of the fact that a via electrode (an extraction electrode) 33 of the second electrode layer 13 is formed at an upper part of the circuit board 1. The via electrode 33 becomes a lower electrode. It is to be noted that extraction of the via electrode 33 of the second electrode layer 13 at a lower part of the circuit board 1 is also possible. Further, the second electrode layer 13 is also connected to other pattern or other capacity on a GND solid surface (not illustrated), and thus, it is possible to have such a configuration that the via electrode is extracted in the up-down direction in proximity to the capacitive device 10.

The frame section 14 has, for example, a laminated structure including a conductive film which is in the same layer as the first electrode layer 12, the dielectric film 11, and metallic foil which is in the same layer as the second electrode layer 13. In the frame section 14, for example, the conductive film and the metallic foil on and below the dielectric film 11 are short-circuited and have a ground potential.

A wiring layer 21 made of copper foil, a prepreg (a resin substrate) 22, and a wiring layer 23 made of copper foil are joined to the capacitive device 10, which form a core substrate 20. Provided on the core substrate 20 is, for example, an upper-layer wiring 30 in which a prepreg 31 and a wiring layer 32 made of copper foil are provided in this order of closeness to the capacitive device 10. The wiring layer 32 includes the via electrodes (the extraction electrodes) 33 connected to the first electrode layer 12 and the second electrode layer 13. Provided below the core substrate 20 is a lower-layer wiring 40 in which a prepreg 41 and a wiring layer 42 made of copper foil are provided in this order of closeness to the capacitive device 10.

An opening 50 is provided in proximity to the capacitive device 10. For instance, the opening 50 passes through the upper-layer wiring 30 and the capacitive device 10, and reaches the prepreg 22 of the core substrate 20. As will be described later, after a short-circuit section that short-circuits the first electrode layer 12 and the second electrode layer 13 is formed, and the core substrate 20, the upper-layer wiring 30, and the lower-layer wiring 40 are formed, the opening 50 is formed by removing the short-circuit section.

As illustrated in Part (B) of FIG. 1, a first leading wiring 51 is provided between the first electrode layer 12 and the opening 50. A second leading wiring 52 is provided between the second electrode layer 13 and the opening 50, as similarly illustrated in Part (B) of FIG. 1. It is preferable that the first leading wiring 51 and the second leading wiring 52 be disposed at the respective positions which do not overlap in an xy plane. Since the first leading wiring 51 and the second leading wiring 52 do not have overlapping portions, it is possible to suppress generation of a parasitic capacitance and thus, the capacitive device 10 of high precision is achievable.

The circuit board 1 may be manufactured as follows, for example.

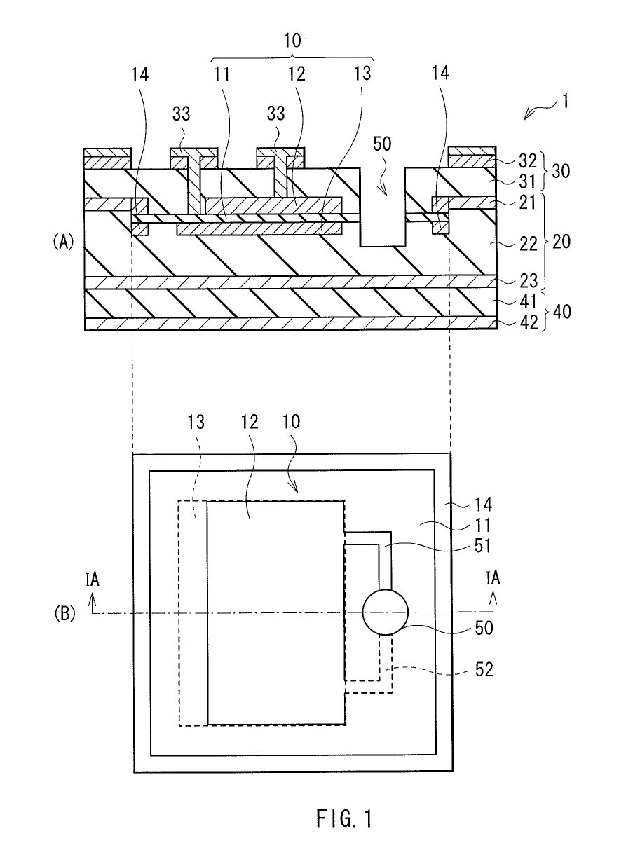

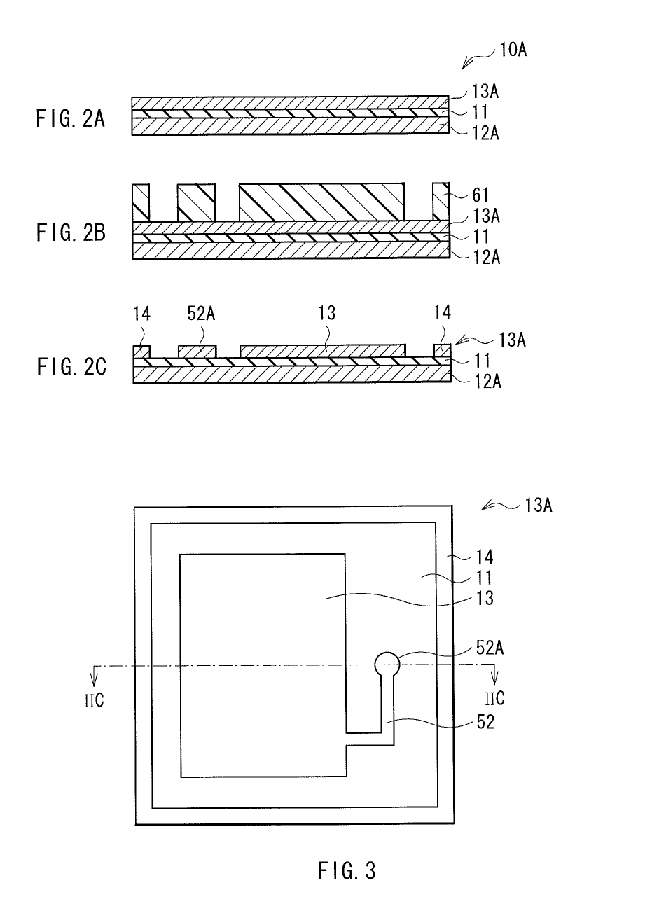

FIG. 2A to FIG. 9C illustrate a method of manufacturing a circuit board 1, in process order. First, as illustrated in FIG. 2A, a capacitive device material 10A in which the dielectric film 11 and a conductive film 13A are laminated in this order on metallic foil 12A is prepared. Like the second electrode layer 13 described above, the metallic foil 12A is not limited in particular in terms of material, but is made of, for example, metallic foil made of metal such as copper and nickel. The conductive film 13A is not limited in particular in terms of material, like the first electrode layer 12 described above. However, the conductive film 13A is, for example, a single-layer conductive film made of metal such as copper and nickel, or a laminated body including a plurality of conductive films made of a plurality of materials.

Next, as illustrated in FIG. 2B, a mask intended to process the conductive film 13A is formed on this conductive film 13A of the capacitive device material 10A, by using a dry film 61 or the like having an opening in a desired region.

The conductive film 13A is then processed using, for example, a solution, and the dry film 61 is removed, as illustrated in FIG. 2C. As a result, the second electrode layer 13 of the capacitive device 10, the second leading wiring 52 extended from the second electrode layer 13, and a land 52A provided at the tip of the second leading wiring 52 are formed as illustrated in FIG. 3.

It is to be noted that, although the case in which the conductive film 13A is patterned first is described here, the metallic foil 12A may be patterned first. When strength in subsequent handling is taken into consideration, it is desirable to pattern the conductive film 13A first.

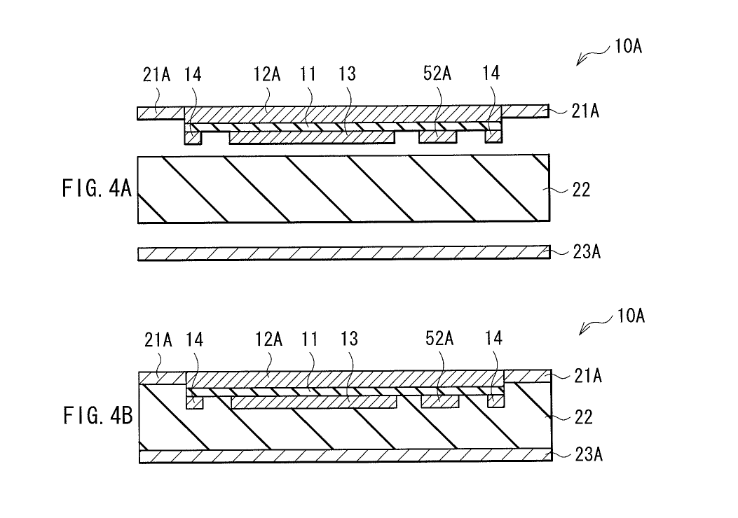

Next, as illustrated in FIG. 4A and FIG. 4B, copper foil 21A having an opening in a desired region, and the capacitive device material 10A matching the opening of the copper foil 21A, and copper foil 23A are adhered to the prepreg 22 by a pressure press method or the like. In this process, an adhesion surface of the capacitive device material 10A is on the patterned conductive film 13A side, and the adhesion is performed by aligning the capacitive device material 10A with the opening of the copper foil 21A.

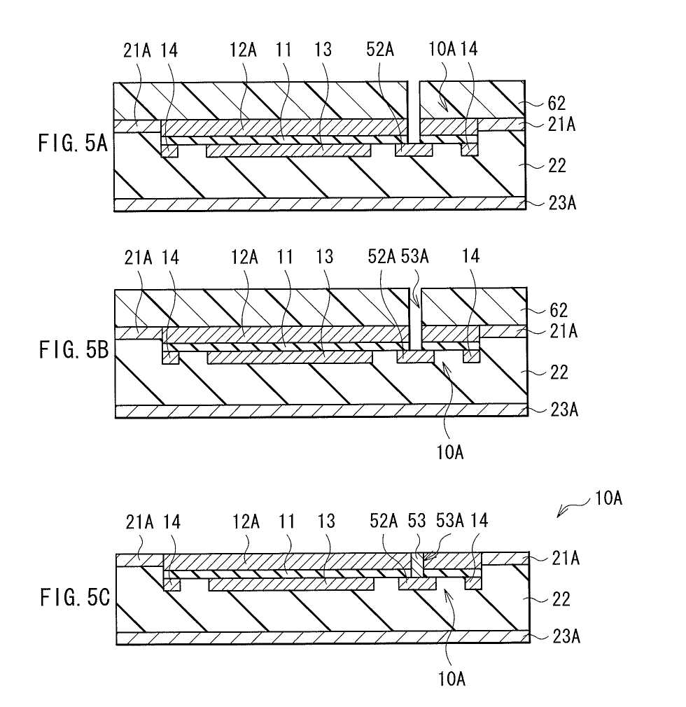

After the copper foil 21A, the copper foil 23A, and the capacitive device material 10A are adhered to the prepreg 22, a mask intended to process the metallic foil 12A is formed on the metallic foil 12A of the capacitive device material 10A, by using a dry film 62 having an opening in a desired region, as illustrated in FIG. 5A. Next, the metallic foil 12A and the dielectric film 11 of the capacitive device material 10A are processed using, for example, a chemical, so that an opening section 53A is formed in the metallic foil 12A and the dielectric film 11, as illustrated in FIG. 5B. This opening section 53A is provided on the land 52A at the tip of the second leading wiring 52. Subsequently, a short-circuit electrode 53 is formed in the opening section 53A, as illustrated FIG. 5C. As a result, the second electrode layer 13 and the metallic foil 12A are short-circuited through the short-circuit electrode 53. Thus, even when a static electricity is stored in a subsequent process, a current is allowed to escape through the short-circuit electrode 53, which suppresses damage to the dielectric film 11.

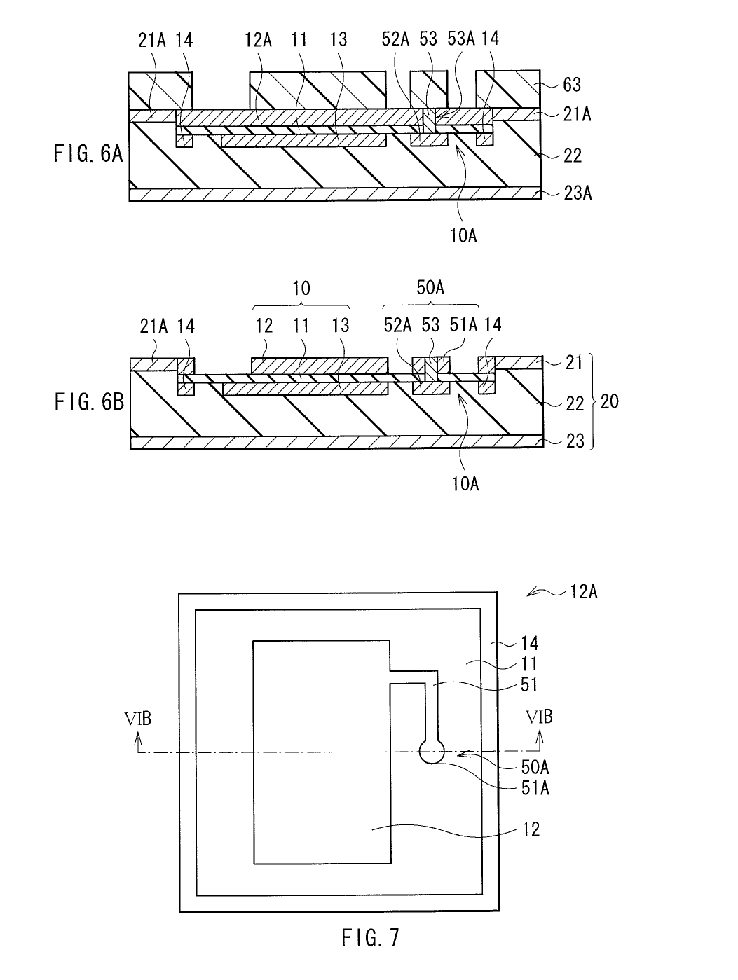

After the short-circuit electrode 53 is formed, a mask intended to process the metallic foil 12A is formed on the metallic foil 12A of the capacitive device material 10A, by using a dry film 63 having an opening in a desired region, as illustrated in FIG. 6A. Subsequently, the metallic foil 12A and the copper foil 21A are processed using, for example, a chemical, and the dry film 63 is removed, as illustrated in FIG. 6B. As a result, the first electrode layer 12 of the capacitive device 10, the first leading wiring 51 extended from the first electrode layer 12, and a land 51A provided at the tip of the first leading wiring 51 are formed as illustrated in FIG. 7. Further, in this process, a mask (not illustrated) is similarly formed also on a back side of the copper foil 23A, so that the copper foil 23A is processed.

The first electrode layer 12 is formed at a position facing the second electrode layer 13, with the dielectric film 11 interposed therebetween. As a result, the capacitive device 10 having the first electrode layer 12 and the second electrode layer 13 with the dielectric film 11 provided therebetween is formed.

The first leading wiring 51 is disposed at a position which does not overlap the position of the second leading wiring 52 in the xy plane. This suppresses occurrence of a parasitic capacitance between the first leading wiring 51 and the second leading wiring 52.

The land 51A provided at the tip of the first leading wiring 51 and the land 52A provided at the tip of the second leading wiring 52 are disposed at the respective positions overlapping in the xy plane, and short-circuited through the short-circuit electrode 53. As a result, a short-circuit section 50A that short-circuits the first electrode layer 12 and the second electrode layer 13 through the short-circuit electrode 53 is formed.

Further, the wiring layer 21 is formed by processing the copper foil 21A, and the wiring layer 23 is formed by processing the copper foil 23A. As a result, the core substrate 20 that includes the capacitive device 10, the wiring layers 21 and 23, and the prepreg 22 is formed as illustrated in FIG. 6B. Here, the first leading wiring 51 extended from the first electrode layer 12 and the second leading wiring 52 extended from the second electrode layer 13 are short-circuited through the short-circuit electrode 53 of the short-circuit section 50A. Therefore, even when a static electricity is stored, a current is allowed to escape through the short-circuit electrode 53, so that damage to the dielectric film 11 is suppressed.

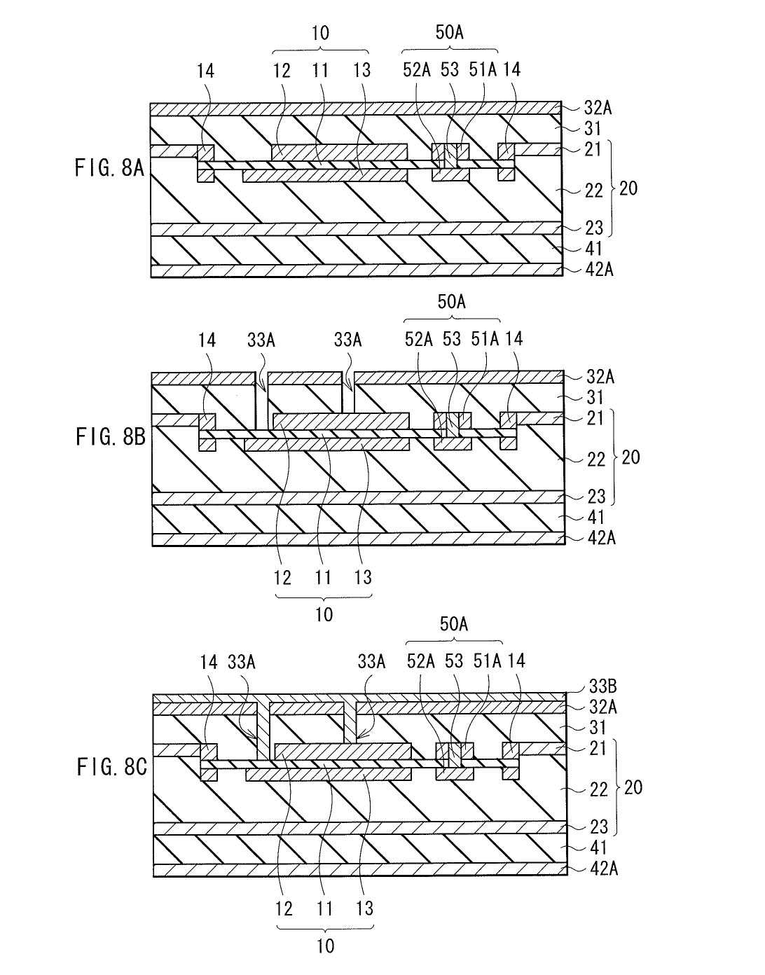

Next, the prepregs 31 and 41, copper foil 32A, and copper foil 42A are adhered to the core substrate 20, as illustrated in FIG. 8A. Subsequently, as illustrated in FIG. 8B, an opening section 33A is formed in the copper foil 32A and the prepreg 31 by laser beam machining. Then, a via-electrode material film 33B is formed on a top surface of the copper foil 32A as well as inside the opening section 33A as illustrated in FIG. 8C.

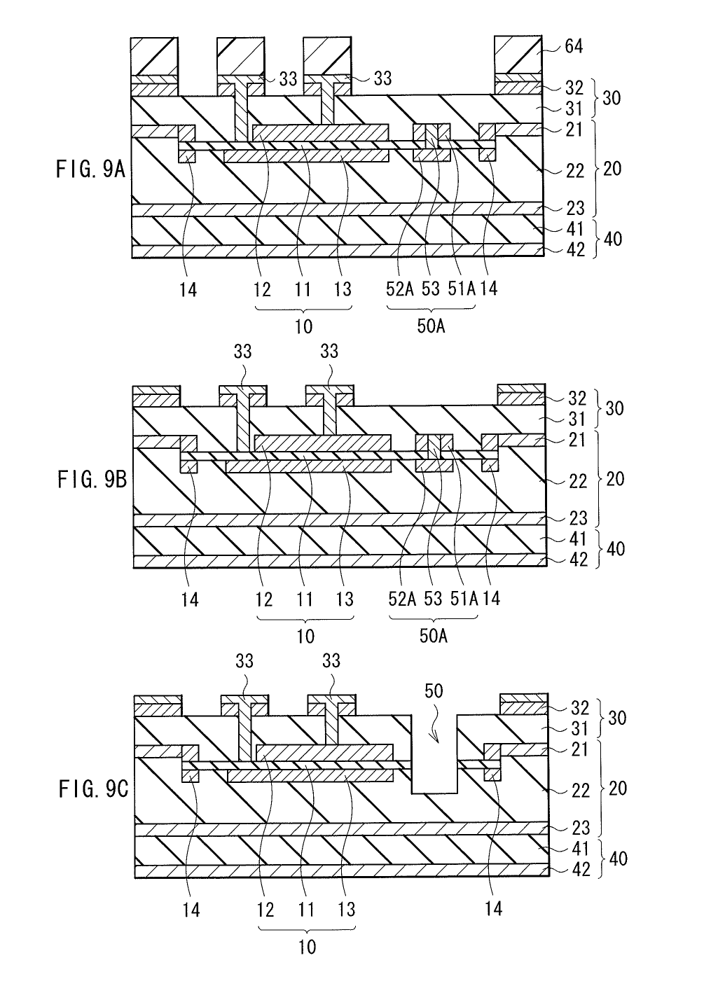

Subsequently, as illustrated in FIG. 9A, a mask intended to process the via-electrode material film 33B and the copper foil 32A is formed on the via-electrode material film 33B, by using a dry film 64 having an opening in a desired region. The via-electrode material film 33B and the copper foil 32A are then processed using, for example, a chemical, so that the wiring layer 32 and the via electrodes 33 are formed, as illustrated in FIG. 9A. As a result, the upper-layer wiring 30 configured of the prepreg 31 and the wiring layer 32 is formed. The dry film 64 is then removed as illustrated in FIG. 9B.

Further, in this process, the copper foil 42A is formed by forming a mask (not illustrated) also on the copper foil 42A on an underside and processing the wiring layer 42. The lower-layer wiring 40 configured of the prepreg 41 and the wiring layer 42 is thereby formed.

After the formation of the upper-layer wiring 30 and the lower-layer wiring 40, the opening 50 is formed using a technique such as laser beam machining and drilling. The short-circuit section 50A configured of the lands 51A and 52A as well as the short-circuit electrode 53 is thereby removed, as illustrated in FIG. 9C.

The opening 50 is provided by removing the short-circuit section 50A. Thus, the lands 51A and 52A overlapping in the xy plane are removed, and only the first leading wiring 51 and the second leading wiring 52 which do not overlap in the xy plane remain as illustrated in Part (B) of FIG. 1. Therefore, occurrence of the parasitic capacitance is suppressed. In addition, a surface of the dielectric film 11 in the opening 50 is rough due to damage caused by the drilling or the like, and thus may be in a condition with a large amount of leakage current. When the lands 51A and 52A remain, there is a possibility that a leakage current will also occur here, through a damaged portion of the dielectric film 11. Complete removal of the lands 51A and 52A overlapping in the xy plane suppresses the occurrence of the leakage current, making it possible to increase reliability of the capacitive device 10.

It is to be noted that, although the opening 50 may be left as it is, it is desirable to seal the opening 50 using a solder resist or the like to further increase the reliability.

In the present embodiment, as described above, the capacitive device 10 having the first electrode layer 12 and the second electrode layer 13 with the dielectric film 11 interposed therebetween is formed using the capacitive device material 10A having the dielectric film 11 and the conductive film 13A in this order on the metallic foil 12A. In addition thereto, the short-circuit section 50A that short-circuits the first electrode layer 12 and the second electrode layer 13 is formed, and this short-circuit section 50A is removed after the formation of the upper-layer wiring 30 and the lower-layer wiring 40. Therefore, even when a static electricity is stored in a process between the formation of the short-circuit section 50A and the formation of the upper-layer wiring 30 and the lower-layer wiring 40, the current is allowed to escape through the short-circuit section 50A. Hence, it is possible to avoid damage to the dielectric film 11 and thereby prevent electrostatic destruction of the dielectric film 11, even after the first electrode layer 12 or the second electrode layer 13 is formed by cutting or processing the metallic foil 12A or the conductive film 13A of the capacitive device material 10A.

In addition, when the short-circuit section 50A is formed, the short-circuit electrode 53 is formed in the opening section 53A provided in the dielectric film 11, and the first electrode layer 12 and the second electrode layer 13 are short-circuited through this short-circuit electrode 53. Therefore, it is possible to form the short-circuit section 50A easily.

### Second Embodiment

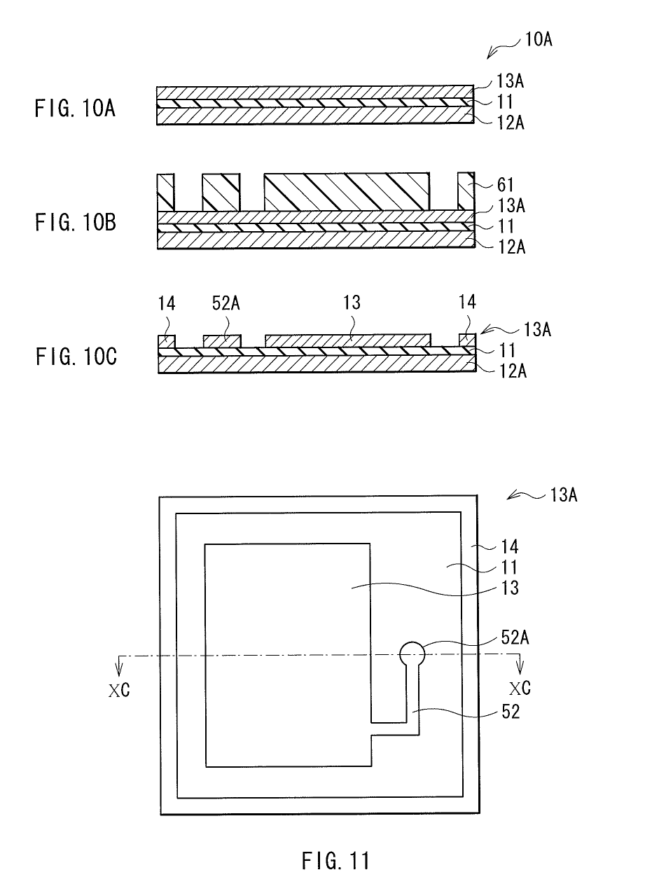

FIG. 10A to FIG. 16C illustrate a method of manufacturing the circuit board 1, according to a second embodiment of the disclosure, in process order. This manufacturing method is different from the method described in the first embodiment in the way of forming the short-circuit section 50A. In other words, in the second embodiment, when the short-circuit section 50A is formed, a damaged section is formed in the dielectric film 11 by laser irradiation, and the first leading wiring 51 extended from the first electrode layer 12 and the second leading wiring 52 extended from the second electrode layer 13 are short-circuited through this damaged section.

First, as illustrated in FIG. 10A, the capacitive device material 10A in which the dielectric film 11 and the conductive film 13A are laminated in this order on the metallic foil 12A is prepared. Then, as illustrated in FIG. 10B, a mask intended to process the conductive film 13A is formed on this conductive film 13A of the capacitive device material 10A, by using the dry film 61 having an opening in a desired region, in a manner similar to that in the first embodiment. Subsequently, as illustrated in FIG. 10C, the conductive film 13A is processed using, for example, a chemical, and the dry film 61 is removed. As a result, the second electrode layer 13 of the capacitive device 10, the second leading wiring 52 extended from the second electrode layer 13, and the land 52A provided at the tip of the second leading wiring 52 are formed as illustrated in FIG. 11.

It is to be noted that, although the case in which the conductive film 13A is patterned first is described here, the metallic foil 12A may be patterned first. When strength in subsequent handling is taken into consideration, it is desirable to pattern the conductive film 13A first.

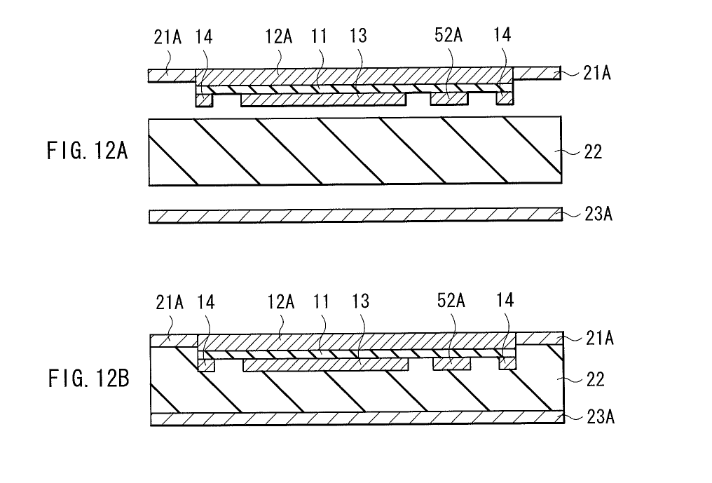

Next, as illustrated in FIG. 12A and FIG. 12B, the copper foil 21A having an opening in a desired region, and the capacitive device material 10A matching with the opening of the copper foil 21A, and the copper foil 23A are adhered to the prepreg 22 by a pressure press method or the like. In this process, an adhesion surface of the capacitive device material 10A is on the patterned conductive film 13A side, and the adhesion is performed by aligning the capacitive device material 10A with the opening of the copper foil 21A.

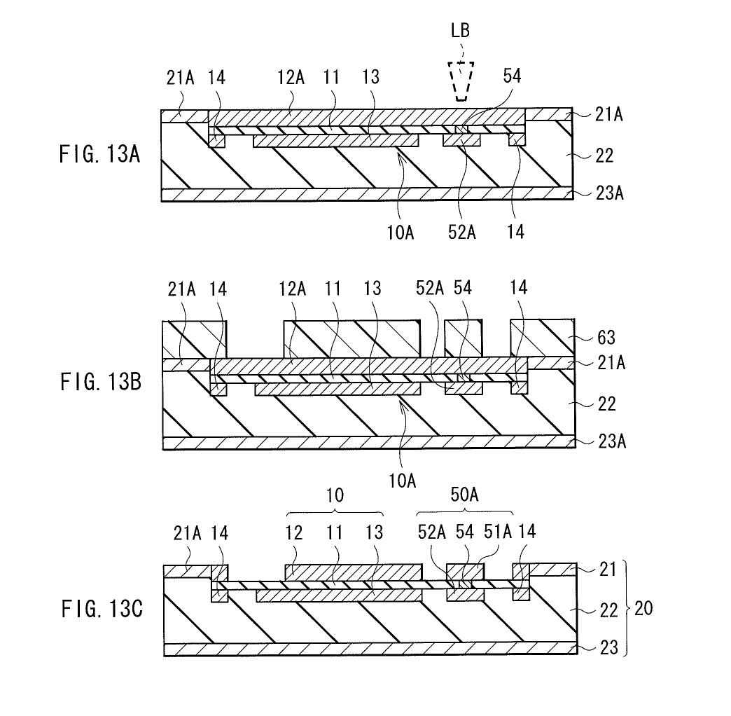

After the copper foil 21A and the copper foil 23A as well as the capacitive device material 10A are adhered to the prepreg 22, a desired region on the metallic foil 12A of the capacitive device material 10A is irradiated with an energy beam such as a laser beam LB, as illustrated in FIG. 13A. As a result, the dielectric film 11 right under an irradiated part is damaged locally and partially, and thereby a damaged section 54 is formed in the dielectric film 11. The damaged section 54 is provided on the land 52A at the tip of the second leading wiring 52. The film quality of the damaged section 54 is impaired, and thereby, a condition in which a leakage current is induced is caused, so that the second electrode layer 13 and the metallic foil 12A are short-circuited through the damaged section 54. Therefore, even when a static electricity is stored in a subsequent process, a current is allowed to escape through the damaged section 54, so that damage to the dielectric film 11 is suppressed.

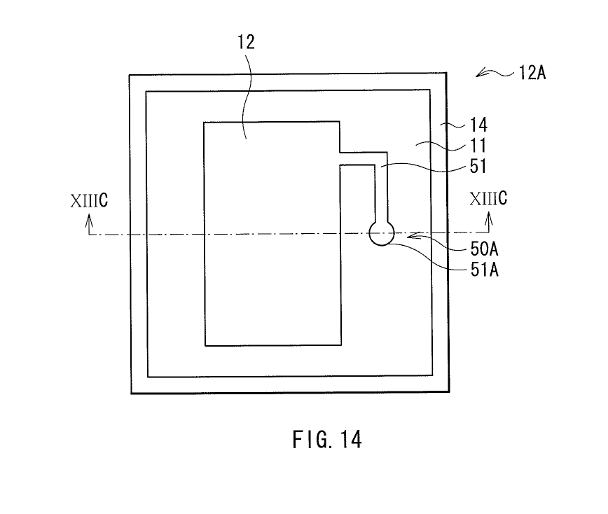

After the formation of the damaged section 54, a mask intended to process the metallic foil 12A is formed on the metallic foil 12A of the capacitive device material 10A, by using the dry film 63 having an opening in a desired region, as illustrated in FIG. 13B. Subsequently, as illustrated in FIG. 13C, the metallic foil 12A and the copper foil 21A are processed using, for example, a chemical, and the dry film 63 is removed. As a result, the first electrode layer 12 of the capacitive device 10, the first leading wiring 51 extended from the first electrode layer 12, and the land 51A provided at the tip of the first leading wiring 51 are formed as illustrated in FIG. 14. Further, in this process, a mask (not illustrated) is similarly formed also on the copper foil 23A on the back side, so that the copper foil 23A is processed.

The first electrode layer 12 is formed at a position facing the second electrode layer 13, with the dielectric film 11 interposed therebetween. As a result, the capacitive device 10 having the first electrode layer 12 and the second electrode layer 13 with the dielectric film 11 therebetween is formed.

The first leading wiring 51 is disposed at a position which does not overlap the second leading wiring 52 in the xy plane. This suppresses occurrence of a parasitic capacitance between the first leading wiring 51 and the second leading wiring 52.

The land 51A provided at the tip of the first leading wiring 51 and the land 52A provided at the tip of the second leading wiring 52 are disposed at the respective positions overlapping in the xy plane, and are short-circuited through the damaged section 54. As a result, the short-circuit section 50A that short-circuits the first electrode layer 12 and the second electrode layer 13 through the damaged section 54 is formed.

Further, the wiring layer 21 is formed by processing the copper foil 21A, and the wiring layer 23 is formed by processing the copper foil 23A. As a result, the core substrate 20, which includes the capacitive device 10, the wiring layers 21 and 23, and the prepreg 22, is formed as illustrated in FIG. 13C. Here, the first leading wiring 51 extended from the first electrode layer 12 and the second leading wiring 52 extended from the second electrode layer 13 are short-circuited through the damaged section 54 of the short-circuit section 50A. Therefore, even when a static electricity is stored, a current is allowed to escape through the damaged section 54, so that damage to the dielectric film 11 is suppressed.

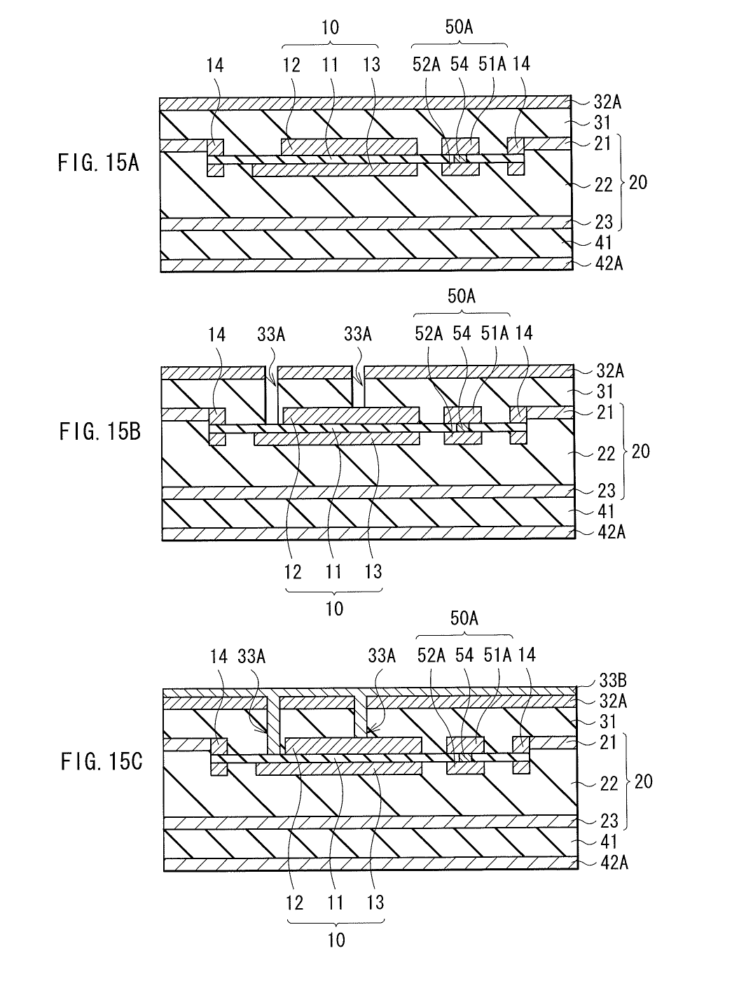

Next, the prepregs 31 and 41 as well as the copper foil 32A and the copper foil 42A are adhered to the core substrate 20, as illustrated in FIG. 15A. Subsequently, as illustrated in FIG. 15B, the opening section 33A is formed in the copper foil 32A and the prepreg 31 by laser beam machining. Then, the via-electrode material film 33B is formed on the top surface of the copper foil 32A and inside the opening section 33A as illustrated in FIG. 15C.

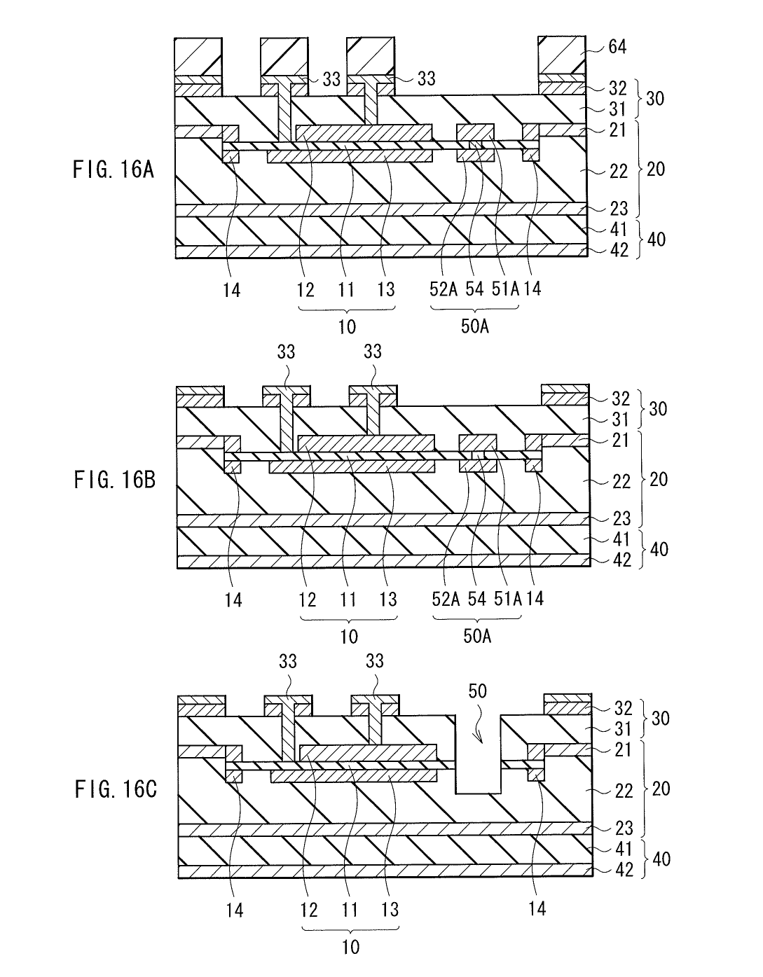

Subsequently, as illustrated in FIG. 16A, a mask intended to process the via-electrode material film 33B and the copper foil 32A is formed on the via-electrode material film 33B, by using the dry film 64 having an opening in a desired region. The via-electrode material film 33B and the copper foil 32A are then processed using, for example, a chemical, so that the wiring layer 32 and the via electrodes 33 are formed, as illustrated in FIG. 16A. As a result, the upper-layer wiring 30 configured of the prepreg 31 and the wiring layer 32 is formed. The dry film 64 is then removed as illustrated in FIG. 16B.

Further, in this process, a mask (not illustrated) is formed also on the copper foil 42A on the underside, and, so that the wiring layer 42 is formed. The lower-layer wiring 40 configured of the prepreg 41 and the wiring layer 42 is thereby formed.

After the formation of the upper-layer wiring 30 and the lower-layer wiring 40, the opening 50 is formed using a technique such as laser beam machining and drilling. The short-circuit section 50A configured of the lands 51A and 52A as well as the damaged section 54 is thereby removed, as illustrated in FIG. 16C.

The opening 50 is provided by removing the short-circuit section 50A. Thus, the lands 51A and 52A overlapping in the xy plane are removed, and only the first leading wiring 51 and the second leading wiring 52 which do not overlap in the xy plane remain as illustrated in Part (B) of FIG. 1. Thus, occurrence of the parasitic capacitance is suppressed. In addition, the surface of the dielectric film 11 in the opening 50 is rough due to damage caused by the drilling or the like, and thus may be in a condition with a large amount of leakage current. When the lands 51A and 52A remain, there is a possibility that a leakage current will also occur here, through a damaged portion of the dielectric film 11. Complete removal of the lands 51A and 52A overlapping in the xy plane suppresses the occurrence of the leakage current, making it possible to increase the reliability of the capacitive device 10.

It is to be noted that, although the opening 50 may be left as it is, it is desirable to seal the opening 50 using a solder resist or the like to further increase the reliability.

In this way, in the present embodiment, the capacitive device 10 having the first electrode layer 12 and the second electrode layer 13 with the dielectric film 11 interposed therebetween is formed using the capacitive device material 10A having the dielectric film 11 and the conductive film 13A in this order on the metallic foil 12A, as in the case of the first embodiment. Further, the short-circuit section 50A that short-circuits the first electrode layer 12 and the second electrode layer 13 is formed, and the short-circuit section 50A is removed after the formation of the upper-layer wiring 30 and the lower-layer wiring 40. Therefore, even when a static electricity is stored in a process from the formation of the short-circuit section 50A to the formation of the upper-layer wiring 30 and the lower-layer wiring 40, the current is allowed to escape through the short-circuit section 50A. Hence, it is possible to avoid damage to the dielectric film 11 and thereby prevent electrostatic destruction of the dielectric film 11, even after the first electrode layer 12 or the second electrode layer 13 is formed by cutting or processing the metallic foil 12A or the conductive film 13A of the capacitive device material 10A.

In addition, in the formation of the short-circuit section 50A, the damaged section 54 is formed in the dielectric film 11 by the irradiation of the laser beam LB, and the first electrode layer 12 and the second electrode layer 13 are short-circuited through this damaged section 54. Therefore, it is possible to form the short-circuit section 50A easily.

### Third Embodiment

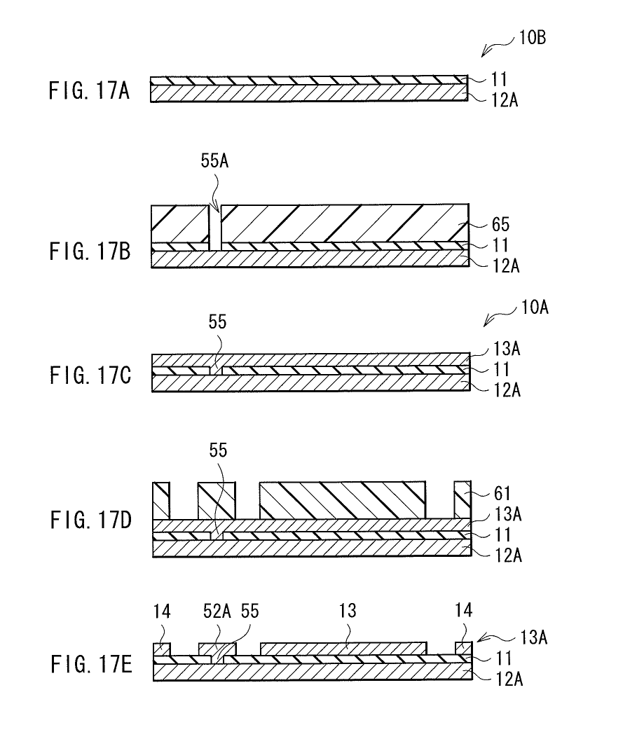

FIG. 17A to FIG. 22C illustrate a method of manufacturing the circuit board 1, according to a third embodiment of the disclosure, in process order. This manufacturing method is different from the method described in the first embodiment in the way of forming the short-circuit section 50A. In other words, in the third embodiment, when the short-circuit section 50A is formed, a contact section between the metallic foil 12A and the conductive film 13A is formed in an opening section provided in the dielectric film 11. The first leading wiring 51 extended from the first electrode layer 12 and the second leading wiring 52 extended from the second electrode layer 13 are short-circuited through this contact section.

First, a base material 10B having the dielectric film 11 made of the material described above is formed on the metallic foil 12A made of the material described above, as illustrated in FIG. 17A. Then, a mask intended to process the dielectric film 11 is formed on the dielectric film 11, by using a dry film 65 having an opening in a desired region, as illustrated in FIG. 17B. Subsequently, the dielectric film 11 is processed using the dry film 65 as a mask, so that an opening section 55A is formed in the dielectric film 11, as illustrated in FIG. 17B. The dry film 65 is then removed.

Next, as illustrated in FIG. 17C, the conductive film 13A made of the material described above is formed on the dielectric film 11. As a result, the capacitive device material 10A, in which the metallic foil 12A, the dielectric film 11, and the conductive film 13A are laminated in this order, is formed. Further, the opening section 55A of the dielectric film 11 is filled with the conductive film 13A, so that a contact section 55 between the metallic foil 12A and the conductive film 13A is formed. In other words, the metallic foil 12A and the conductive film 13A are short-circuited through the contact section 55. Therefore, even when a static electricity is stored in a subsequent process, a current is allowed to escape through the contact section 55, so that damage to the dielectric film 11 is suppressed.

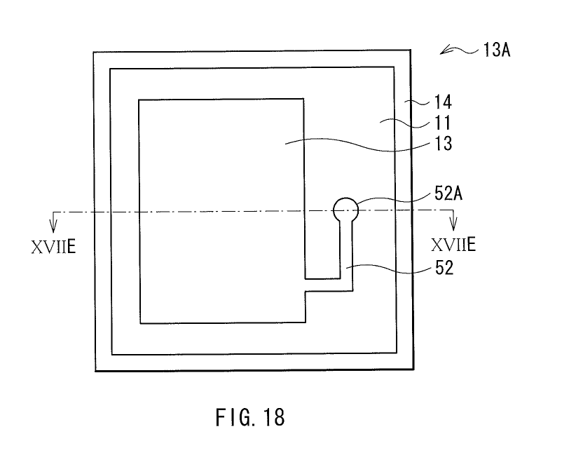

After the formation of the contact section 55, a mask intended to process the conductive film 13A is formed on the conductive film 13A, by using the dry film 61 having an opening in a desired region, as illustrated in FIG. 17D. The conductive film 13A is then processed using, for example, a chemical, and the dry film 61 is removed, as illustrated in FIG. 17E. As a result, the second electrode layer 13 of the capacitive device 10, the second leading wiring 52 extended from the second electrode layer 13, and the land 52A provided at the tip of the second leading wiring 52 are formed as illustrated in FIG. 18. The land 52A is formed on the contact section 55.

It is to be noted that, although the case in which the conductive film 13A is patterned first is described here, the metallic foil 12A may be patterned first. When strength in subsequent handling is taken into consideration, it is desirable to pattern the conductive film 13A first.

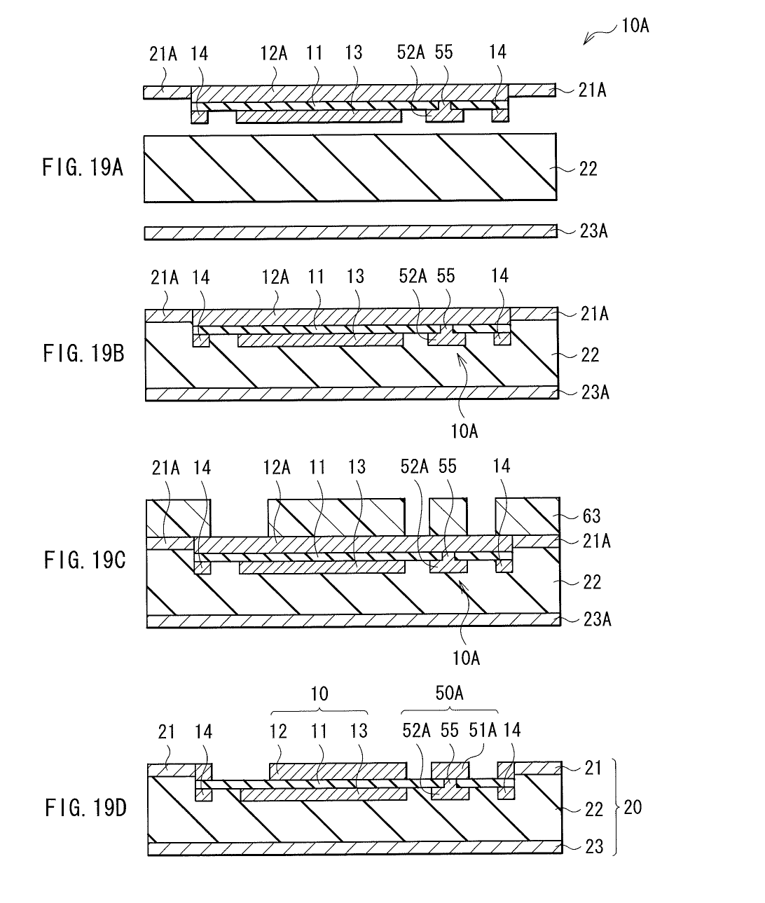

Next, as illustrated in FIG. 19A and FIG. 19B, the copper foil 21A having an opening in a desired region, and the capacitive device material 10A matching with the opening of the copper foil 21A, and the copper foil 23A are adhered to the prepreg 22 by a pressure press method or the like. In this process, the adhesion surface of the capacitive device material 10A is on the patterned conductive film 13A side, and the adhesion is performed by aligning the capacitive device material 10A with the opening of the copper foil 21A.

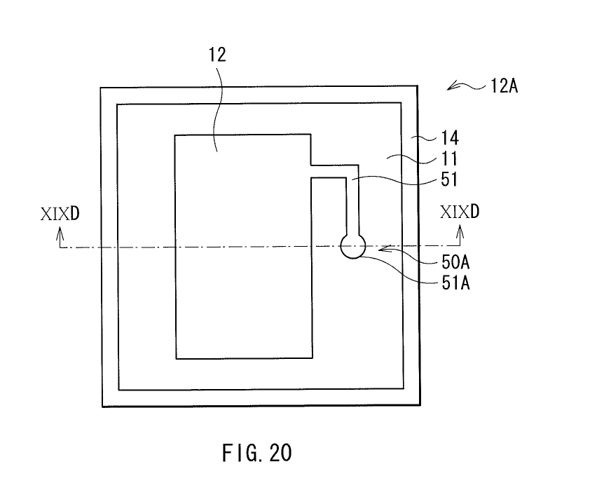

After the copper foil 21A and the copper foil 23A as well as the capacitive device material 10A are adhered to the prepreg 22, a mask intended to process the metallic foil 12A is formed on the metallic foil 12A of the capacitive device material 10A, by using the dry film 63 having an opening in a desired region, as illustrated in FIG. 19C. The metallic foil 12A and the copper foil 21A are then processed using, for example, a chemical, and the dry film 63 is removed, as illustrated in FIG. 19D. As a result, the first electrode layer 12 of the capacitive device 10, the first leading wiring 51 extended from the first electrode layer 12, and the land 51A provided at the tip of the first leading wiring 51 are formed as illustrated in FIG. 20. Further, in this process, a mask (not illustrated) is similarly formed also on the copper foil 23A on the back side, so that the copper foil 23A is processed.

The first electrode layer 12 is formed at a position facing the second electrode layer 13, with the dielectric film 11 interposed therebetween. As a result, the capacitive device 10 having the first electrode layer 12 and the second electrode layer 13 with the dielectric film 11 provided therebetween is formed.

The first leading wiring 51 is disposed at a position which does not overlap the second leading wiring 52 in the xy plane. This prevents occurrence of a parasitic capacitance between the first leading wiring 51 and the second leading wiring 52.

The land 51A provided at the tip of the first leading wiring 51 and the land 52A provided at the tip of the second leading wiring 52 are disposed at the respective positions overlapping in the xy plane, and short-circuited through the contact section 55. As a result, the short-circuit section 50A that short-circuits the first electrode layer 12 and the second electrode layer 13 through the contact section 55 is formed.

Further, the wiring layer 21 is formed by processing the copper foil 21A, and the wiring layer 23 is formed by processing the copper foil 23A. As a result, the core substrate 20, which includes the capacitive device 10, the wiring layers 21 and 23, and the prepreg 22, is formed as illustrated in FIG. 19D. Here, the first leading wiring 51 extended from the first electrode layer 12 and the second leading wiring 52 extended from the second electrode layer 13 are short-circuited through the contact section 55 of the short-circuit section 50A. Therefore, even when a static electricity is stored, a current is allowed to escape through the contact section 55, so that damage to the dielectric film 11 is suppressed.

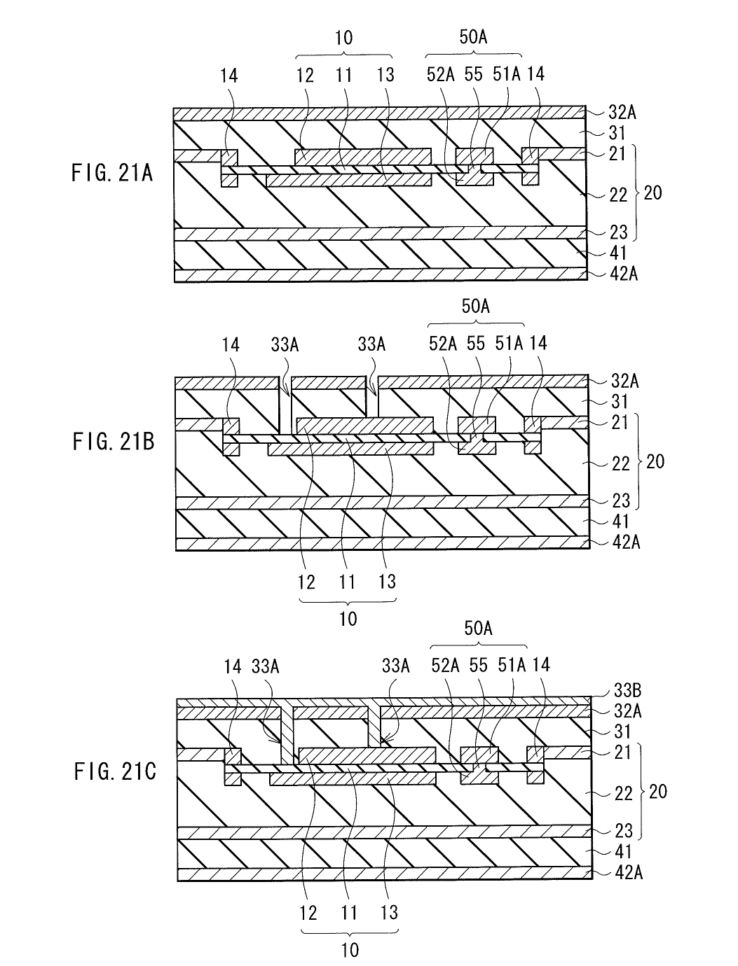

Next, the prepregs 31 and 41 as well as the copper foil 32A and the copper foil 42A are adhered to the core substrate 20, as illustrated in FIG. 21A. Subsequently, as illustrated in FIG. 21B, the opening section 33A is formed in the copper foil 32A and the prepreg 31 by laser beam machining. Then, the via-electrode material film 33B is formed on the top surface of the copper foil 32A and inside the opening section 33A as illustrated in FIG. 21C.

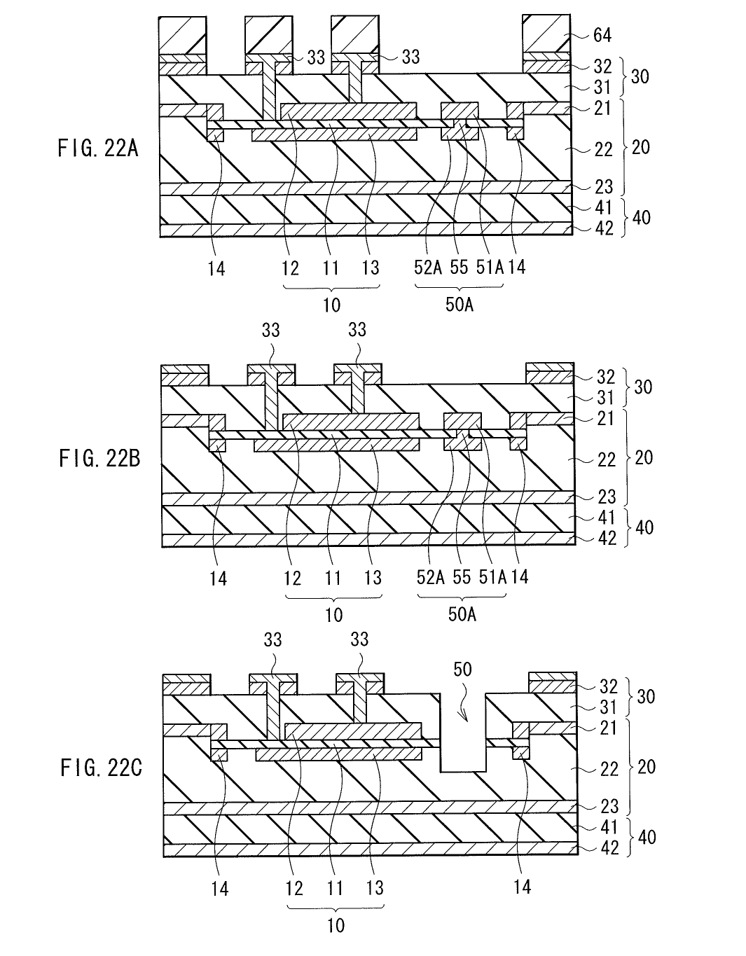

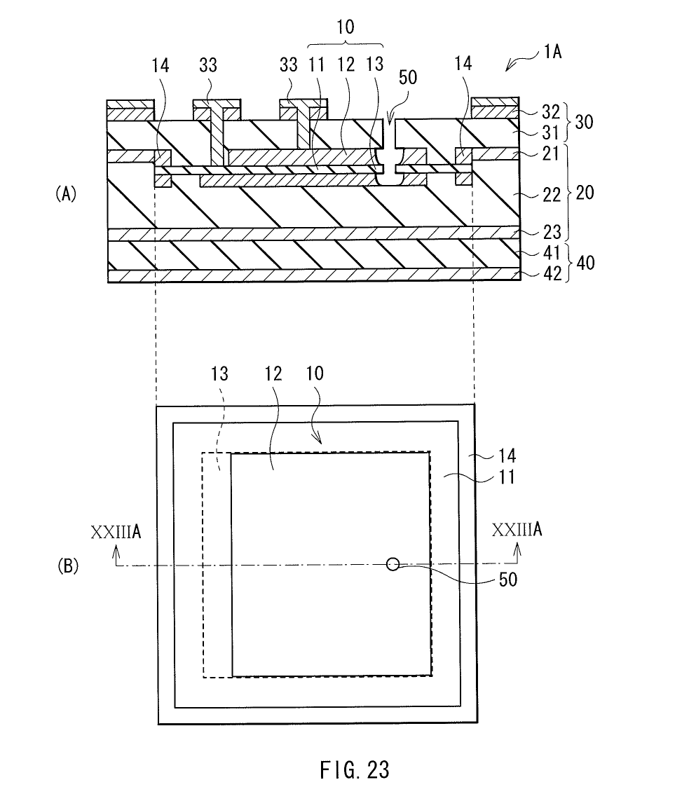

Subsequently, as illustrated in FIG. 22A, a mask intended to process the via-electrode material film 33B and the copper foil 32A is formed on the via-electrode material film 33B, by using the dry film 64 or the like having an opening in a desired region. The via-electrode material film 33B and the copper foil 32A are then processed using, for example, a chemical, so that the wiring layer 32 and the via electrodes 33 are formed, as illustrated in FIG. 22A. As a result, the upper-layer wiring 30 configured of the prepreg 31 and the wiring layer 32 is formed. The dry film 64 is then removed as illustrated in FIG. 22B.

Further, in this process, a mask (not illustrated) is formed also on the copper foil 42A on the underside and the copper foil 42A is processed, so that the wiring layer 42 is formed. The lower-layer wiring 40 configured of the prepreg 41 and the wiring layer 42 is thereby formed.

After the formation of the upper-layer wiring 30 and the lower-layer wiring 40, the opening 50 is formed using a technique such as laser beam machining and drilling. The short-circuit section 50A configured of the lands 51A and 52A as well as the short-circuit section 50A is thereby removed, as illustrated in FIG. 22C.

The opening 50 is provided by removing the short-circuit section 50A. Thus, the lands 51A and 52A overlapping in the xy plane are removed, and only the first leading wiring 51 and the second leading wiring 52 which do not overlap in the xy plane remain as illustrated in Part (B) of FIG. 1. Thus, occurrence of the parasitic capacitance is suppressed. In addition, the surface of the dielectric film 11 in the opening 50 is rough due to damage caused by the drilling or the like, and thus may be in a condition with a large amount of leakage current. When the lands 51A and 52A remain, there is a possibility that a leakage current will also occur here, through a damaged part of the dielectric film 11. Complete removal of the lands 51A and 52A overlapping in the xy plane suppresses the generation of the leakage current, making it possible to increase the reliability of the capacitive device 10.

It is to be noted that, although the opening 50 may be left as it is, it is desirable to seal the opening 50 using a solder resist or the like to further increase the reliability.

In this way, in the present embodiment, the capacitive device 10 having the first electrode layer 12 and the second electrode layer 13 with the dielectric film 11 interposed therebetween is formed using the capacitive device material 10A having the dielectric film 11 and the conductive film 13A in this order on the metallic foil 12A, as in the case of the first embodiment. Further, the short-circuit section 50A that short-circuits the first electrode layer 12 and the second electrode layer 13 is formed, and the short-circuit section 50A is removed after the formation of the upper-layer wiring 30 and the lower-layer wiring 40. Therefore, even when a static electricity is stored in a process between the formation of the short-circuit section 50A and the formation of the upper-layer wiring 30 and the lower-layer wiring 40, the current is allowed to escape through the short-circuit section 50A. Hence, it is possible to avoid damage to the dielectric film 11 and thereby prevent electrostatic destruction of the dielectric film 11, even after the first electrode layer 12 or the second electrode layer 13 is formed by cutting or processing the metallic foil 12A or the conductive film 13A of the capacitive device material 10A.

In addition, in the formation of the capacitive device material 10A, the contact section 55 between the metallic foil 12A and the conductive film 13A is formed in the opening section 55A, by forming the conductive film 13A after providing the opening section 55A in the dielectric film 11, through the use of the base material 10B having the dielectric film 11 on the metallic foil 12A. Therefore, even when the dielectric film 11 is a thin film, it is possible to suppress electrostatic destruction of the dielectric film 11 in the process of forming the capacitive device material 10A.

Moreover, in the formation of the short-circuit section 50A, the first electrode layer 12 and the second electrode layer 13 are short-circuited through the contact section 55 provided in the capacitive device material 10A. Therefore, it is possible to form the short-circuit section 50A easily.

### Fourth Embodiment

Part (A) and Part (B) of FIG. 23A illustrate a cross-sectional configuration and a plane configuration, respectively, of a circuit board 1A according to a fourth embodiment of the disclosure. This circuit board 1A has the opening 50 provided inside the first electrode layer 12 and the second electrode layer 13, without providing the first leading wiring 51 and the second leading wiring 52. Except for this, the circuit board 1A has the same configuration, function, and effects as those of the circuit board 1 described in the first embodiment. Therefore, the components corresponding to those of the first embodiment will be provided with the same characters as those of the first embodiment.

The capacitive device 10, the core substrate 20, the upper-layer wiring 30, and the lower-layer wiring 40 are configured in a manner similar to that of the first embodiment.

The opening 50 is provided inside the first electrode layer 12 and the second electrode layer 13 of the capacitive device 10. In the present embodiment, the first leading wiring 51 and the second leading wiring 52 are unnecessary, which makes it possible to reduce an area occupied by the capacitive device 10.

The circuit board 1A may be manufactured as follows, for example.

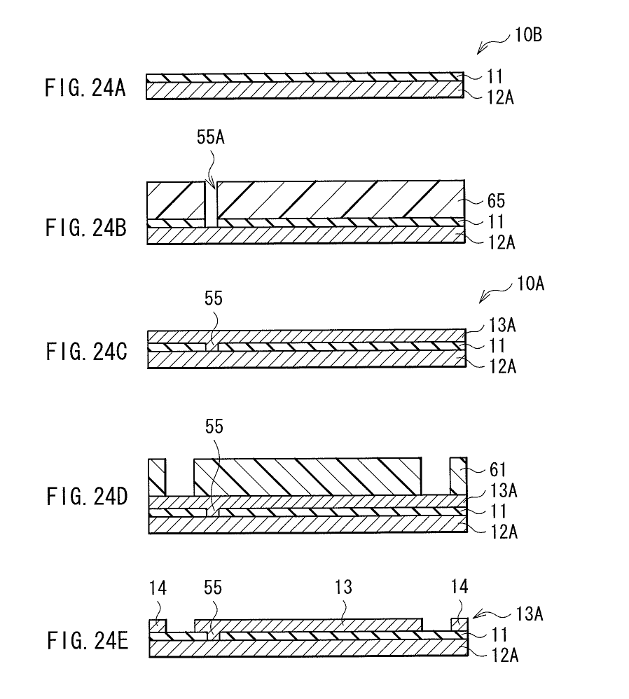

FIG. 24A to FIG. 30B illustrate a method of manufacturing the circuit board 1A in process order. It is to be noted that this circuit board 1A may be manufactured using any of the short-circuit section 50A having the short-circuit electrode 53 of the first embodiment, the short-circuit section 50A having the damaged section 54 of the second embodiment, and the short-circuit section 50A having the contact section 55 of the third embodiment. A case of using the short-circuit section 50A having the contact section 55 of the third embodiment will be described below, for example.

First, the base material 10B having the dielectric film 11 made of the material described above is formed on the metallic foil 12A made of the material described above, as illustrated in FIG. 24A. Then, a mask intended to process the dielectric film 11 is formed on the dielectric film 11, by using the dry film 65 having an opening in a desired region, as illustrated in FIG. 24B. Subsequently, the dielectric film 11 is processed using the dry film 65 as a mask, so that the opening section 55A is formed in the dielectric film 11, as illustrated in FIG. 24B. The dry film 65 is removed.

Subsequently, as illustrated in FIG. 24C, the conductive film 13A made of the material described above is formed on the dielectric film 11. As a result, the capacitive device material 10A in which the metallic foil 12A, the dielectric film 11, and the conductive film 13A are laminated in this order is formed. Further, the opening section 55A of the dielectric film 11 is filled with the conductive film 13A, so that the contact section 55 between the metallic foil 12A and the conductive film 13A is formed. In other words, the metallic foil 12A and the conductive film 13A are short-circuited through the contact section 55. Therefore, even when a static electricity is stored in a subsequent process, a current is allowed to escape through the contact section 55, so that damage to the dielectric film 11 is suppressed.

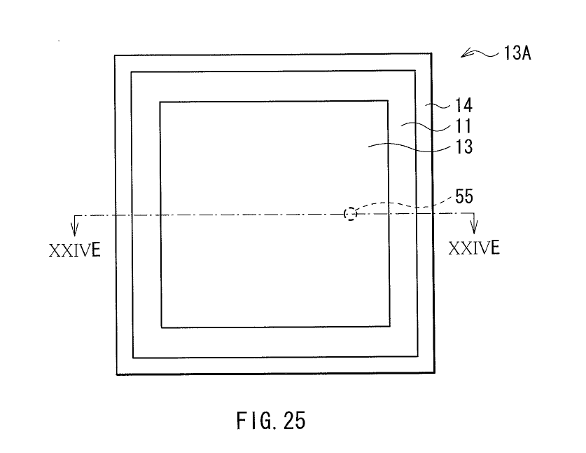

After the formation of the contact section 55, a mask intended to process the conductive film 13A is formed on the conductive film 13A, by using the dry film 61 having an opening in a desired region, as illustrated in FIG. 24D. Subsequently, the conductive film 13A is processed using, for example, a chemical, and the dry film 61 is removed, as illustrated in FIG. 24E. As a result, the second electrode layer 13 of the capacitive device 10 is formed as illustrated in FIG. 25. The second electrode layer 13 is formed in a region including the contact section 55. The second leading wiring 52 and the land 52A are not formed.

It is to be noted that, although the case in which the conductive film 13A is patterned first is described here, the metallic foil 12A may be patterned first. When strength in subsequent handling is taken into consideration, it is desirable to pattern the conductive film 13A first.

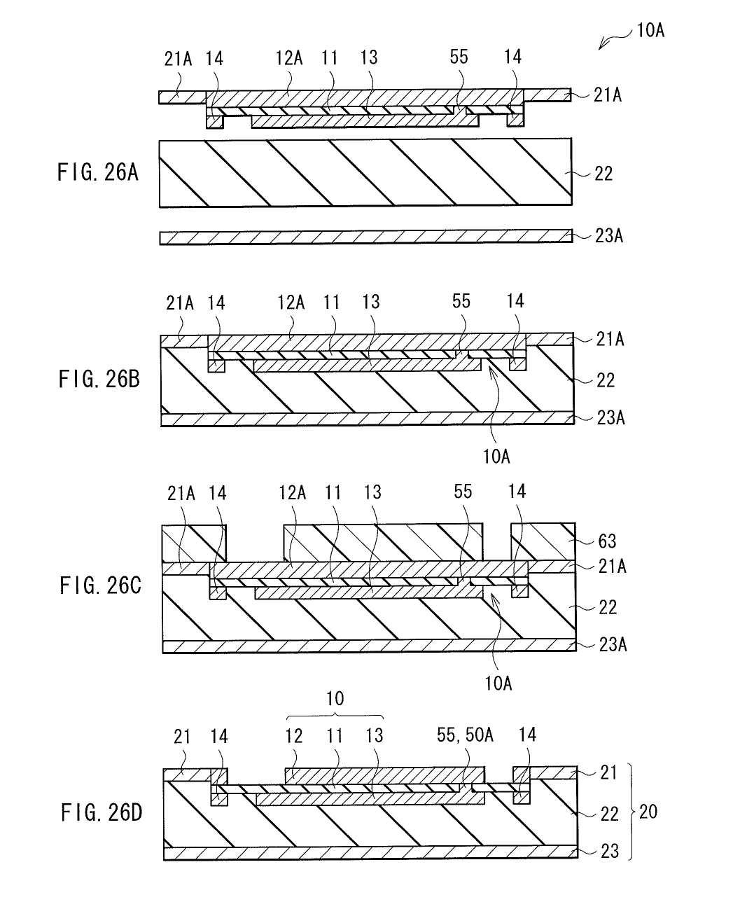

Next, as illustrated in FIG. 26A and FIG. 26B, the copper foil 21A having an opening in a desired region, and the capacitive device material 10A matching with the opening of the copper foil 21A, and the copper foil 23A are adhered to the prepreg 22 by a pressure press method or the like. In this process, the adhesion surface of the capacitive device material 10A is on the patterned conductive film 13A side, and the adhesion is performed by aligning the capacitive device material 10A with the opening section of the copper foil 21A.

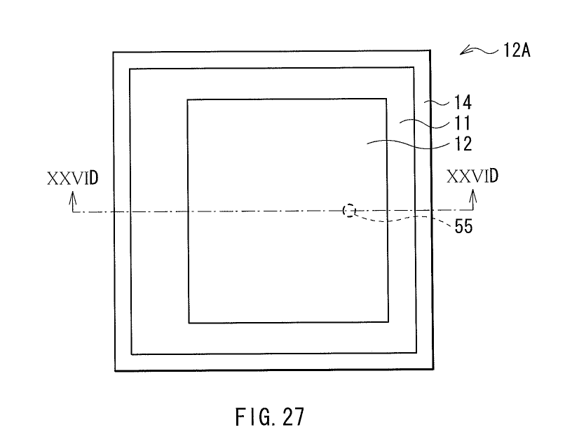

After the copper foil 21A and the copper foil 23A as well as the capacitive device material 10A are adhered to the prepreg 22, a mask intended to process the metallic foil 12A is formed on the metallic foil 12A of the capacitive device material 10A, by using the dry film 63 having an opening in a desired region, as illustrated in FIG. 26C. Next, the metallic foil 12A and the copper foil 21A are processed using, for example, a chemical, and the dry film 63 is removed, as illustrated in FIG. 26D. As a result, the first electrode layer 12 of the capacitive device 10 is formed as illustrated in FIG. 27. The first electrode layer 12 is formed in a region including the contact section 55. The first leading wiring 51 and the land 51A are not formed. Further, in this process, a mask (not illustrated) is similarly formed also on the copper foil 23A on the back side, so that the copper foil 23A is processed.

The first electrode layer 12 is formed at a position facing the second electrode layer 13, with the dielectric film 11 interposed therebetween. As a result, the capacitive device 10 having the first electrode layer 12 and the second electrode layer 13 with the dielectric film 11 provided therebetween is formed. Further, the short-circuit section 50A that short-circuits the first electrode layer 12 and the second electrode layer 13 through the contact section 55 is formed inside the first electrode layer 12 and the second electrode layer 13.

Further, the wiring layer 21 is formed by processing the copper foil 21A, and the wiring layer 23 is formed by processing the copper foil 23A. As a result, the core substrate 20 which includes the capacitive device 10, the wiring layers 21 and 23, and the prepreg 22 is formed as illustrated in FIG. 26D. Here, the first electrode layer 12 and the second electrode layer 13 are short-circuited through the contact section 55 of the short-circuit section 50A. Therefore, even when a static electricity is stored, a current is allowed to escape through the contact section 55, so that damage to the dielectric film 11 is suppressed.

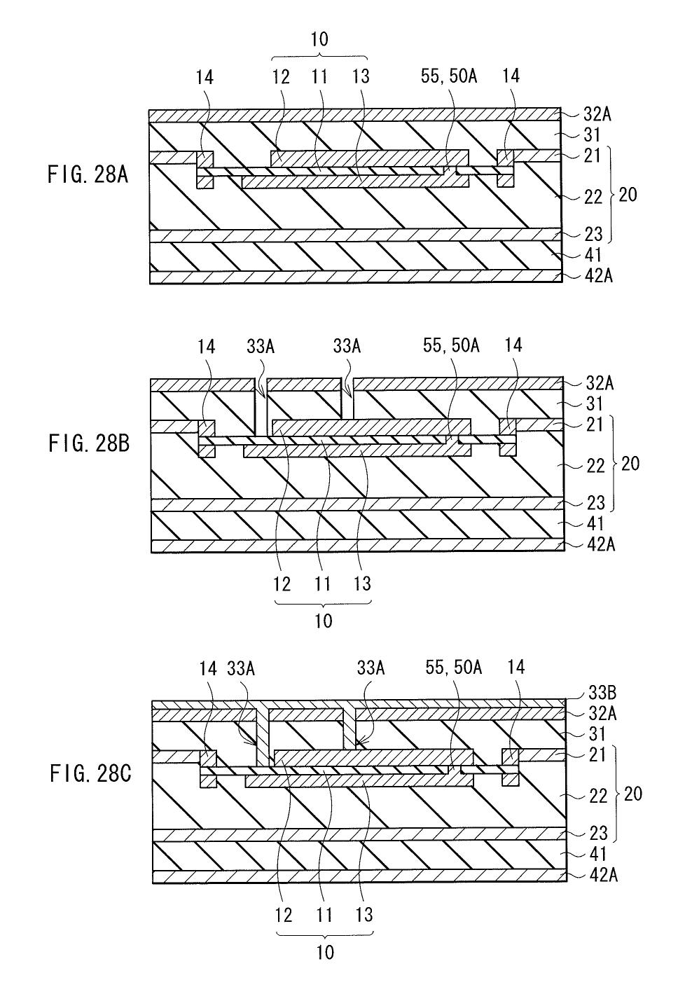

Next, the prepregs 31 and 41 as well as the copper foil 32A and the copper foil 42A are adhered to the core substrate 20, as illustrated in FIG. 28A. Subsequently, as illustrated in FIG. 28B, the opening section 33A is provided in the copper foil 32A and the prepreg 31 by laser beam machining. Then, the via-electrode material film 33B is formed on the top surface of the copper foil 32A and inside the opening section 33A as illustrated in FIG. 28C.

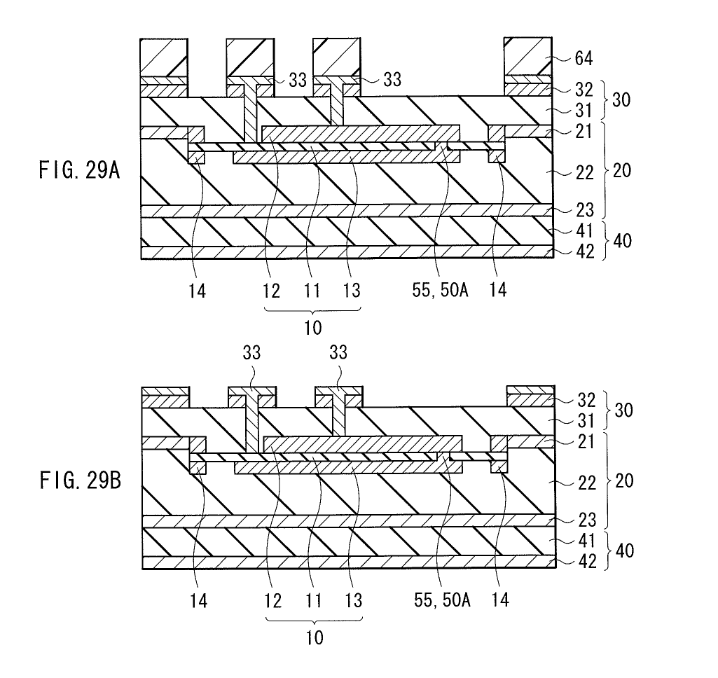

Subsequently, as illustrated in FIG. 29A, a mask intended to process the via-electrode material film 33B and the copper foil 32A is formed on the via-electrode material film 33B, by using the dry film 64 or the like having an opening in a desired region. The via-electrode material film 33B and the copper foil 32A are then processed using, for example, a chemical, so that the wiring layer 32 and the via electrodes 33 are formed, as illustrated in FIG. 29A. As a result, the upper-layer wiring 30 configured of the prepreg 31 and the wiring layer 32 is formed. The dry film 64 is then removed as illustrated in FIG. 29B.

Further, in this process, a mask (not illustrated) is formed also on the copper foil 42A on the underside and the copper foil 42A is processed so that the wiring layer 42 is formed. The lower-layer wiring 40 configured of the prepreg 41 and the wiring layer 42 is thereby formed.

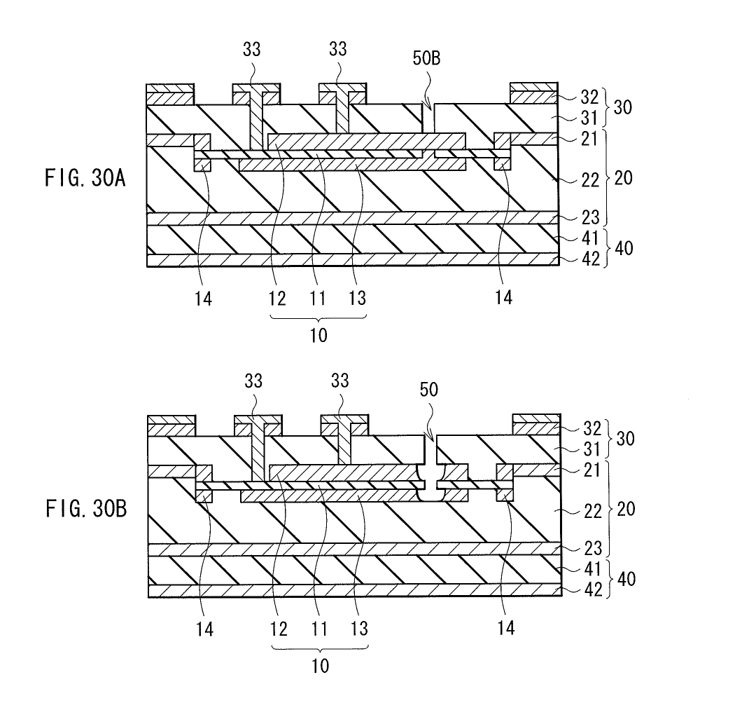

After the formation of the upper-layer wiring 30 and the lower-layer wiring 40, the opening 50B is formed in the prepreg 31, by using a technique such as laser beam machining and drilling, as illustrated in FIG. 30A. Subsequently, as illustrated in FIG. 30B, the opening 50 is further provided by etching the first electrode layer 12 and the dielectric film 11 through use of, for example, a chemical, and the short-circuit section 50A configured of the contact section 55 is removed. Removal of the dielectric film 11 using the chemical suppresses damage to the surface of the dielectric film 11 in the opening 50, which makes it possible to reduce the leakage current.

As illustrated in FIG. 23B, the first leading wiring 51 and the second leading wiring 52 are eliminated by providing the short-circuit section 50A or the opening 50 in the inside of the first electrode layer 12 and the second electrode layer 13. This allows a reduction in the area occupied by the capacitive device 10.

It is to be noted that, although the openings 50 and 50B may be left as they are, it is desirable to seal the openings 50 and 50B using a solder resist or the like to further increase the reliability.

In this way, in the present embodiment, the short-circuit section 50A is provided inside the first electrode layer 12 and the second electrode layer 13. Thus, in addition to producing the effects of the first embodiment, it is possible to eliminate the first leading wiring 51 and the second leading wiring 52, which allows a reduction in the area occupied by the capacitive device 10.

### Fifth Embodiment

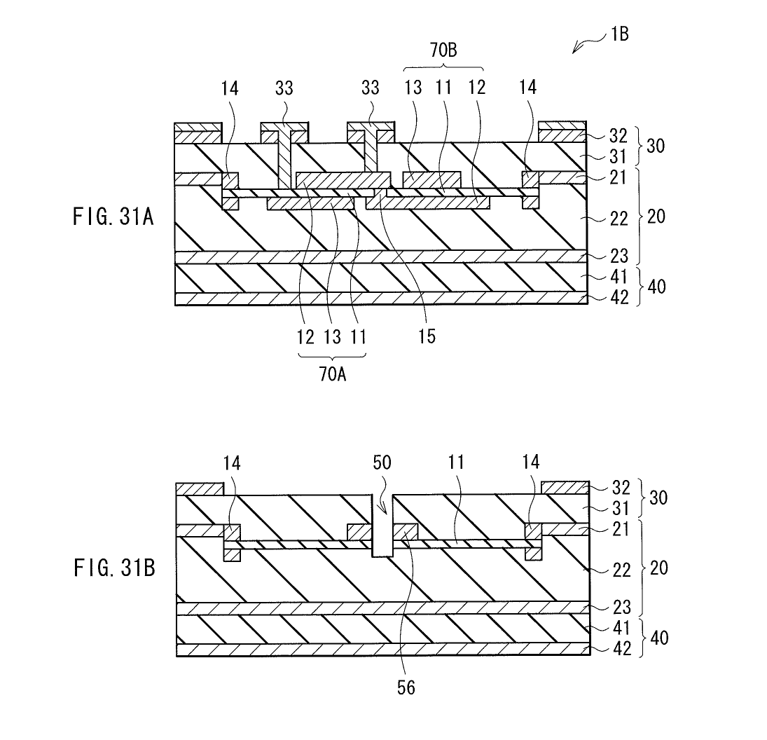

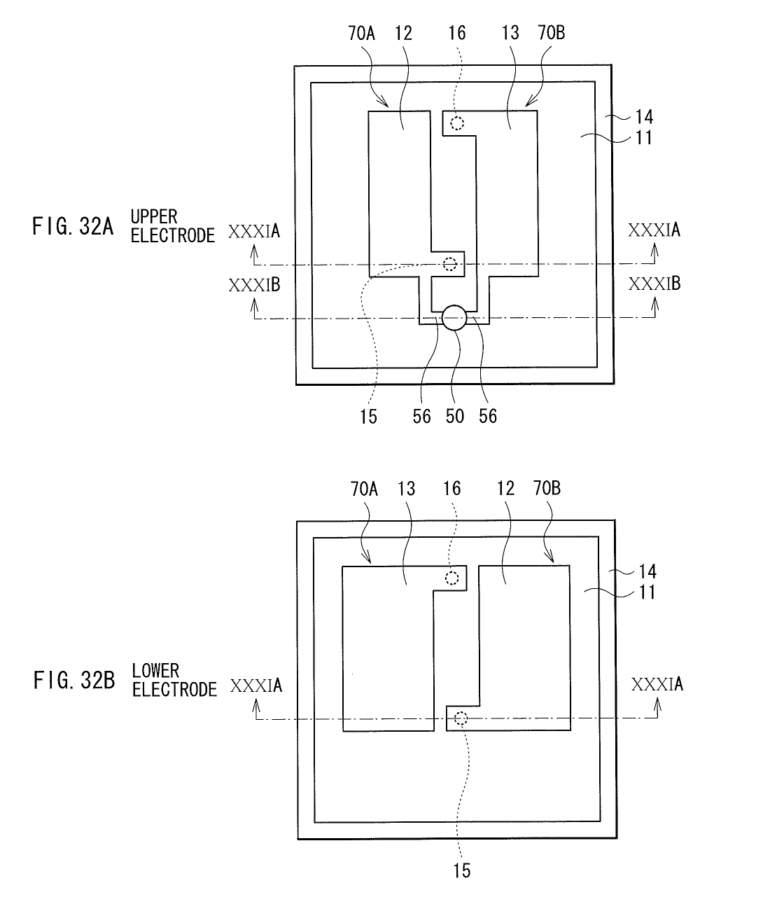

FIGS. 31A and 31B each illustrate a cross-sectional configuration of a circuit board 1B according to a fifth embodiment of the disclosure. FIGS. 32A and 32B each illustrate a plane configuration thereof. This circuit board 1B has a configuration in which a first capacitive device 70A and a second capacitive device 70B are disposed in proximity to each other.

The first capacitive device 70A and the second capacitive device 70B are, for example, quadrangles (rectangles) of the same size. The first capacitive device 70A has the first electrode layer 12 of a first polarity (e.g., +) on a top surface of the dielectric film 11, and the second electrode layer 13 of a second polarity (e.g., −) on an undersurface of the dielectric film 11. The second capacitive device 70B has the second electrode layer 13 of the second polarity (e.g., −) on the top surface of the dielectric film 11, and the first electrode layer 12 of the first polarity (e.g., +) on the undersurface of the dielectric film 11.

The dielectric film 11, the first electrode layer 12, and the second electrode layer 13 are configured in a manner similar to the first embodiment.

The first electrode layer 12 of the first capacitive device 70A and the first electrode layer 12 of the second capacitive device 70B are connected by a first connection section 15. The second electrode layer 13 of the first capacitive device 70A and the second electrode layer 13 of the second capacitive device 70B are connected by a second connection section 16.

A wiring layer 21 made of copper foil, a prepreg (a resin substrate) 22, and a wiring layer 23 made of copper foil are jointed to the first capacitive device 70A and the second capacitive device 70B, which form a core substrate 20. Disposed on the core substrate 20 is an upper-layer wiring 30 including a prepreg 31 and a wiring layer 32 made of copper foil which are provided in this order of closeness to the capacitive device 10. The wiring layer 32 includes via electrodes (extraction electrodes) 33 connected to the first electrode layer 12 and the second electrode layer 13. Disposed below the core substrate 20 is a lower-layer wiring 40 including a prepreg 41 and a wiring layer 42 made of copper foil which are provided in this order of closeness to the capacitive device 10.

As illustrated in FIG. 32A, a routed wiring 56 is provided between the first electrode layer 12 of the first capacitive device 70A and the second electrode layer 13 of the second capacitive device 70B. This routed wiring 56 is disconnected by the opening 50. For instance, the opening 50 passes through the upper-layer wiring 30, the routed wiring 56, and the dielectric film 11, and reaches the prepreg 22 of the core substrate 20. As will be described later, the opening 50 is formed by disconnecting the routed wiring 56, after the routed wiring 56 is formed as a short-circuit section that short-circuits the first electrode layer 12 of the first capacitive device 70A and the second electrode layer 13 of the second capacitive device 70B, and the core substrate 20, the upper-layer wiring 30, and the lower-layer wiring 40 are formed.

The circuit board 1B may be manufactured as follows, for example.

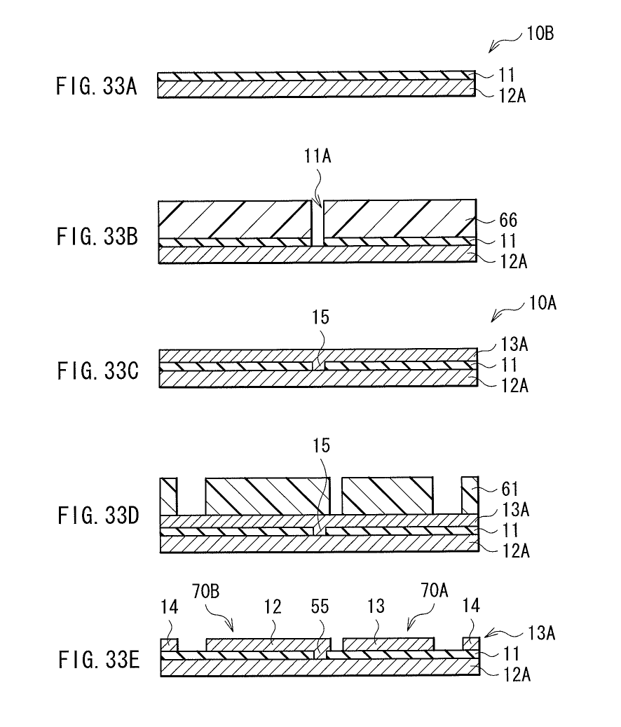

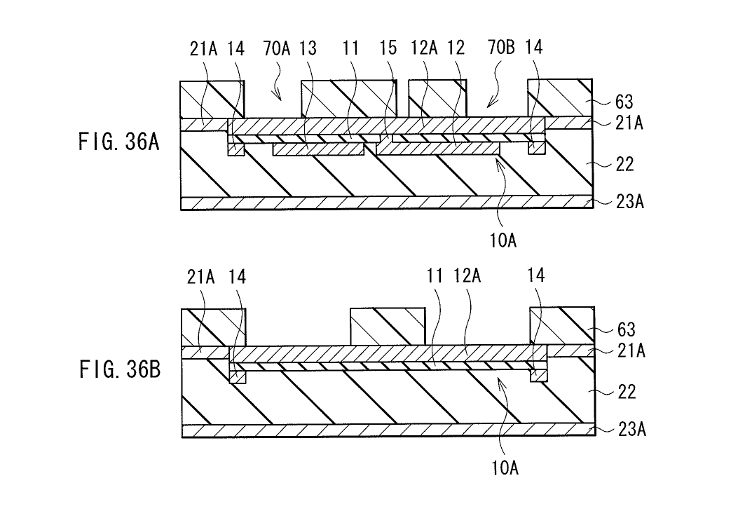

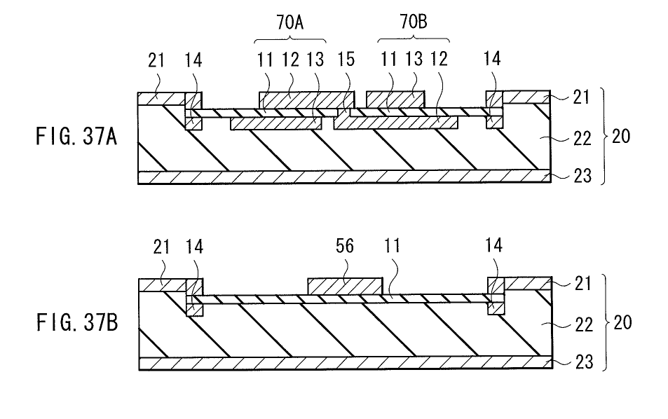

FIG. 33A to FIG. 44B illustrate a method of manufacturing the circuit board 1B in process order. It is to be noted that FIG. 33A to FIG. 35B illustrate the same cross section in consecutive different processes, specifically, a cross section taken along a line XXXIA-XXXIA in FIGS. 32A and 32B. As for FIGS. 36A and 36B to FIGS. 44A and 44B, each pair of the figures illustrate different cross sections in the same process. In other words, FIGS. 36A, 37A, and so on each illustrate a cross section taken along the line XXXIA-XXXIA in FIG. 32A, and FIGS. 36B, 37B, and so on each illustrate a cross section taken along a line XXXIB-XXXIB in FIG. 32B.

First, a base material 10B having a dielectric film 11 made of the material described above is formed on the metallic foil 12A made of the material described above, as illustrated in FIG. 33A. Then, a mask intended to process the dielectric film 11 is formed on the dielectric film 11, by using a dry film 66 having an opening in a desired region, as illustrated in FIG. 33B. Subsequently, the dielectric film 11 is processed using the dry film 65 as a mask, so that an opening section 11A is formed in the dielectric film 11, as illustrated in FIG. 33B. This opening section 11A is provided to form each of the first connection section 15 and the second connection section 16. The dry film 66 is then removed.

Subsequently, as illustrated in FIG. 33C, a conductive film 13A made of the material described above is formed on the dielectric film 11. As a result, the capacitive device material 10A in which the metallic foil 12A, the dielectric film 11, and the conductive film 13A are laminated in this order is formed. Further, the opening section 11A of the dielectric film 11 is filled with the conductive film 13A, so that each of the first connection section 15 and the second connection section 16 is formed. It is to be noted that only the first connection section 15 is illustrated in FIG. 33C.

The first connection section 15 and the second connection section 16 are allowed to have a function similar to that of the contact section 55 in the third embodiment. In other words, the metallic foil 12A and the conductive film 13A are short-circuited through the first connection section 15 and the second connection section 16. Therefore, even when a static electricity is stored in a subsequent process, a current is allowed to escape through the first connection section 15 and the second connection section 16, so that damage to the dielectric film 11 is suppressed.

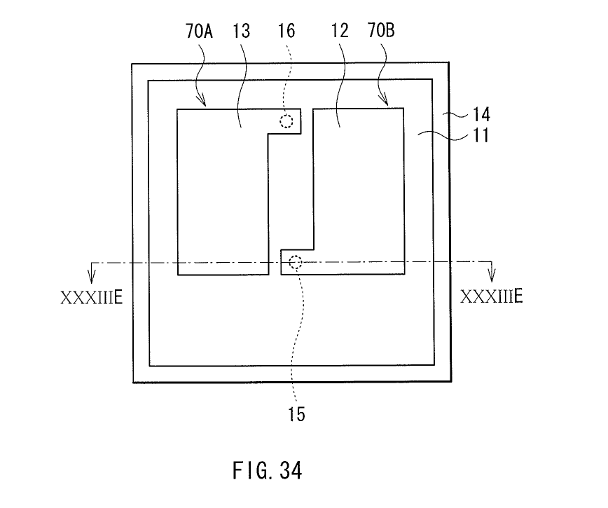

After the formation of the first connection section 15 and the second connection section 16, a mask intended to process the conductive film 13A is formed on the conductive film 13A, by using a dry film 61 having an opening in a desired region, as illustrated in FIG. 33D. Subsequently, the conductive film 13A is processed using, for example, a chemical, and the dry film 61 is removed, as illustrated in FIG. 33E. As a result, the second electrode layer 13 of the first capacitive device 70A and the first electrode layer 12 of the second capacitive device 70B are formed as illustrated in FIG. 34.

It is to be noted that, although the case in which the conductive film 13A is patterned first is described here, the metallic foil 12A may be patterned first. When strength in subsequent handling is taken into consideration, it is desirable to pattern the conductive film 13A first.

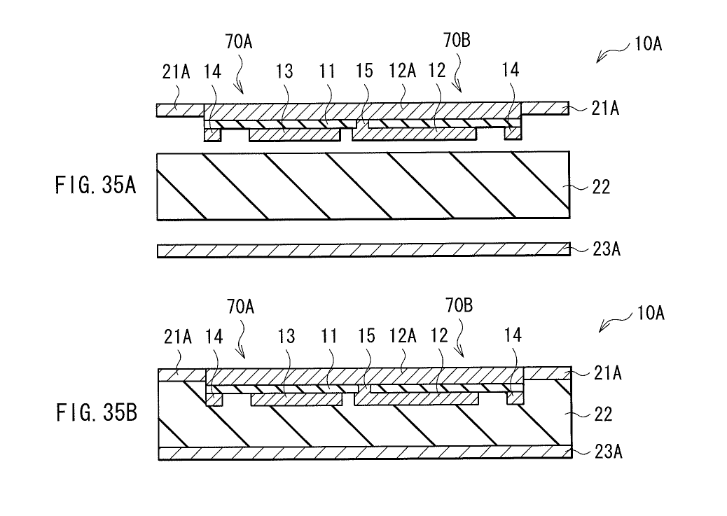

Next, as illustrated in FIG. 35A and FIG. 35B, copper foil 21A having an opening in a desired region, and the capacitive device material 10A matching with the opening of the copper foil 21A, and copper foil 23A are adhered to the prepreg 22 by a pressure press method or the like. In this process, an adhesion surface of the capacitive device material 10A is on the patterned conductive film 13A side, and the adhesion is performed by aligning the capacitive device material 10A with the opening of the copper foil 21A.

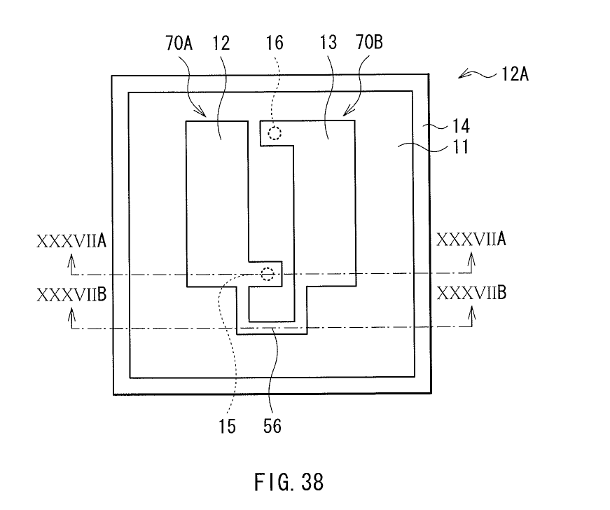

After the copper foil 21A and the copper foil 23A as well as the capacitive device material 10A are adhered to the prepreg 22, a mask intended to process the metallic foil 12A is formed on the metallic foil 12A of the capacitive device material 10A, by using a dry film 63 or the like having an opening in a desired region, as illustrated in FIGS. 36A and 36B. Next, the metallic foil 12A and the copper foil 21A are processed using, for example, a chemical, and the dry film 63 is removed, as illustrated in FIGS. 37A and 37B. As a result, the first electrode layer 12 of the first capacitive device 70A, the second electrode layer 13 of the second capacitive device 70B, and the routed wiring 56 are formed as illustrated in FIG. 38. Further, in this process, a mask (not illustrated) is similarly formed also on the copper foil 23A on a back side, so that the copper foil 23A is processed.

The first electrode layer 12 of the first capacitive device 70A is formed at a position facing the second electrode layer 13 of the first capacitive device 70A, with the dielectric film 11 interposed therebetween. As a result, the first capacitive device 70A which has the first electrode layer 12 on the top surface of the dielectric film 11 and the second electrode layer 13 on the undersurface of the dielectric film 11 is formed.

The second electrode layer 13 of the second capacitive device 70B is formed at a position facing the first electrode layer 12 of the second capacitive device 70B, with the dielectric film 11 interposed therebetween. As a result, the second capacitive device 70B which has the second electrode layer 13 on the top surface of the dielectric film 11 and the first electrode layer 12 on the undersurface of the dielectric film 11 is formed.

Further, the first electrode layer 12 of the first capacitive device 70A and the first electrode layer 12 of the second capacitive device 70B are connected through the first connection section 15. The second electrode layer 13 of the first capacitive device 70A and the second electrode layer 13 of the second capacitive device 70B are connected through the second connection section 16.

Furthermore, the first electrode layer 12 of the first capacitive device 70A and the second electrode layer 13 of the second capacitive device 70B are short-circuited through the routed wiring 56. As a result, the short-circuit section 50A that short-circuits the first electrode layer 12 and the second electrode layer 13 through the routed wiring 56 is formed.

Moreover, the wiring layer 21 is formed by processing the copper foil 21A, and the wiring layer 23 is formed by processing the copper foil 23A. As a result, the core substrate 20 which includes the capacitive device 10, the wiring layers 21 and 23, and the prepreg 22 is formed as illustrated in FIGS. 37A and 37B. Here, the first electrode layer 12 and the second electrode layer 13 are short-circuited through the routed wiring 56 of the short-circuit section 50A. Therefore, even when a static electricity is stored, a current is allowed to escape through the routed wiring 56, so that damage to the dielectric film 11 is suppressed.

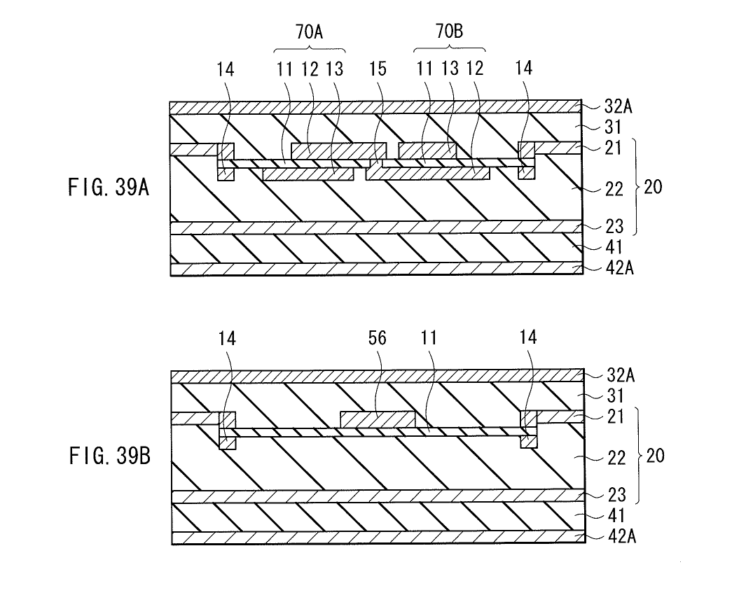

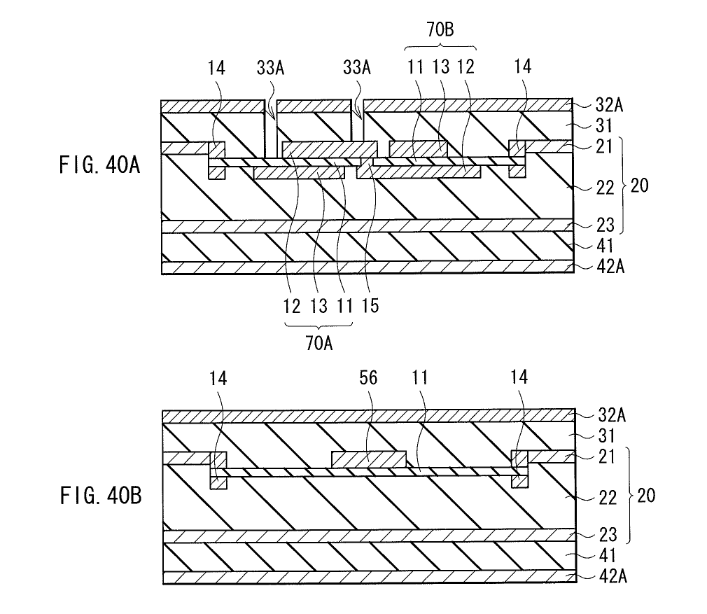

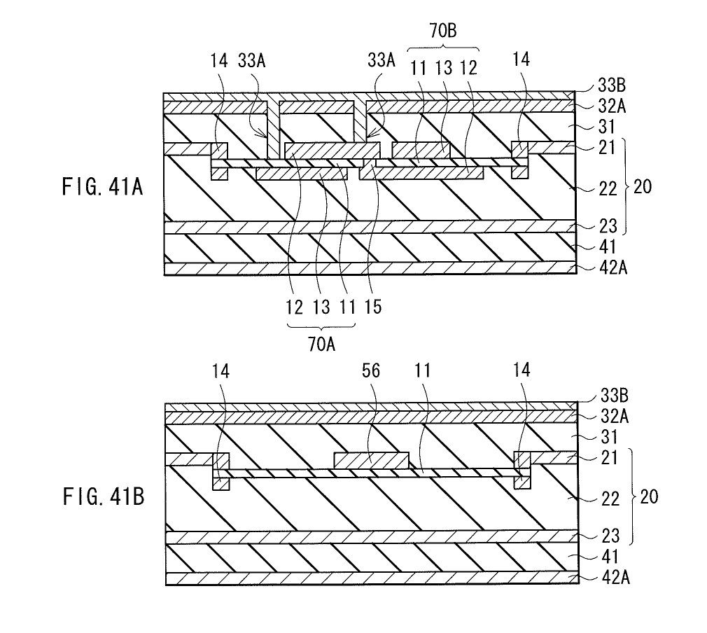

Next, the prepregs 31 and 41 as well as copper foil 32A and copper foil 42A are adhered to the core substrate 20, as illustrated in FIGS. 39A and 39B. Subsequently, as illustrated in FIGS. 40A and 40B, an opening section 33A is formed in the copper foil 32A and the prepreg 31 by laser beam machining. Then, a via-electrode material film 33B is formed on a top surface of the copper foil 32A and inside the opening section 33A as illustrated in FIGS. 41A and 41B.

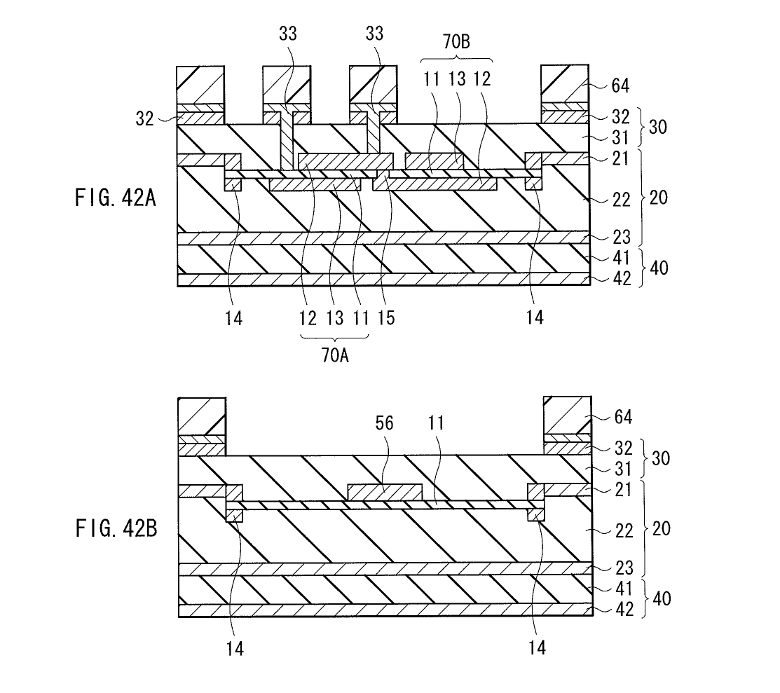

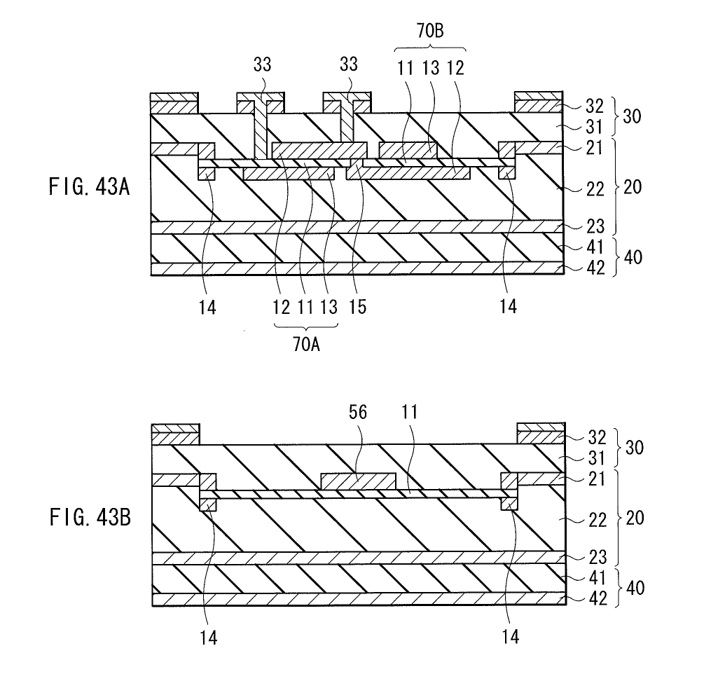

Subsequently, as illustrated in FIGS. 42A and 42B, a mask intended to process the via-electrode material film 33B and the copper foil 32A is formed on the via-electrode material film 33B, by using a dry film 64 having an opening in a desired region. The via-electrode material film 33B and the copper foil 32A are then processed using, for example, a chemical, so that the wiring layer 32 and the via electrodes 33 are formed, as illustrated in FIGS. 42A and 42B. As a result, the upper-layer wiring 30 configured of the prepreg 31 and the wiring layer 32 is formed. The dry film 64 is removed as illustrated in FIGS. 43A and 43B.

Further, in this process, a mask (not illustrated) is formed also on the copper foil 42A on an underside and the copper foil 42A is processed so that the wiring layer 42 is formed. The lower-layer wiring 40 configured of the prepreg 41 and the wiring layer 42 is thereby formed.

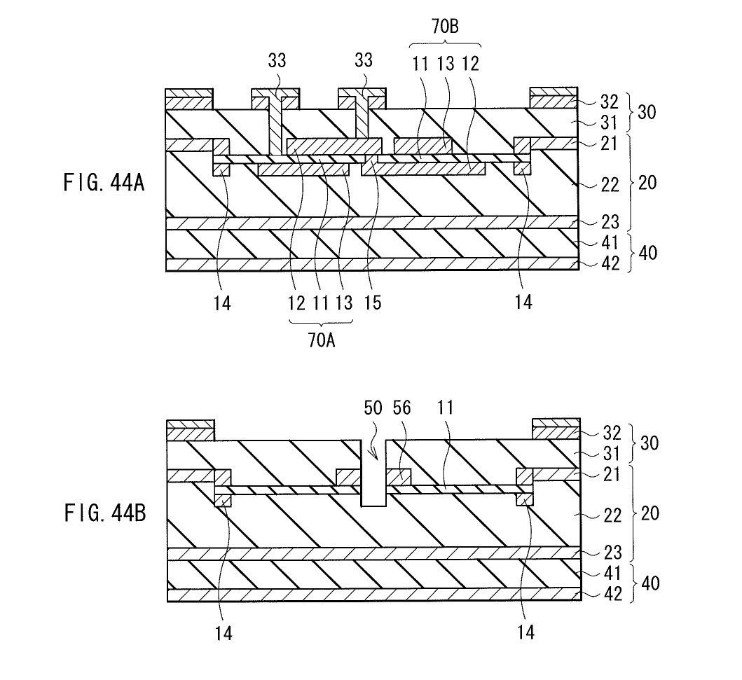

After the formation of the upper-layer wiring 30 and the lower-layer wiring 40, the opening 50 is formed using a technique such as laser beam machining and drilling, as illustrated in FIGS. 44A and 44B. The short-circuit section 50A configured of the routed wiring 56 is thereby disconnected.

Here, the short-circuit section 50A which short-circuits the first electrode layer 12 of the first capacitive device 70A and the second electrode layer 13 of the second capacitive device 70B through the routed wiring 56 is formed. Thus, the first electrode layer 12 of the first capacitive device 70A and the second electrode layer 13 of the second capacitive device 70B are allowed to be short-circuited in the same plane. Therefore, the lands 51A and 52A in the first to third embodiments are unnecessary, which allows the opening 50 to be reduced in size and depth. In addition, as a matter of course, the routed wiring 56 has an advantage that there is no parasitic capacitance.

It is to be noted that, although the opening 50 may be left as it is, it is desirable to seal the opening 50 using a solder resist or the like to further increase the reliability.

In this way, in the present embodiment, there is formed the short-circuit section 50A that short-circuits the first electrode layer 12 of the first capacitive device 70A and the second electrode layer 13 of the second capacitive device 70B through the routed wiring 56. Thus, it is possible to short-circuit the first electrode layer 12 of the first capacitive device 70A and the second electrode layer 13 of the second capacitive device 70B in the same plane, in addition to producing the effects of the first embodiment. Therefore, the lands 51A and 52A in the first to third embodiments are unnecessary, which allows the opening 50 to be reduced in size and depth.

### Sixth Embodiment

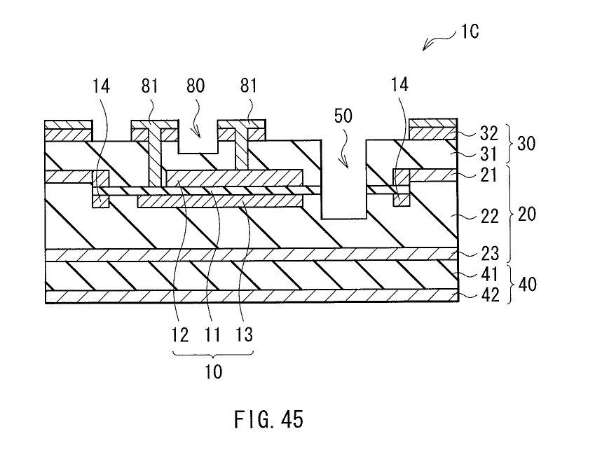

FIG. 45 illustrates a cross-sectional configuration of a circuit board 1C according to a sixth embodiment of the disclosure. In this circuit board 1C, an exterior wiring short-circuit section 81 and an opening 80 that divides this exterior wiring short-circuit section 81 are provided in a wiring layer 32 of an upper-layer wiring 30 that is to be an exterior wiring. Except for this, the circuit board 1C has a configuration, function, and effects similar to those of the circuit board 1 in the first embodiment. Therefore, the elements corresponding to those of the first embodiment will be described by being provided with the same characters as those of the first embodiment.

The capacitive device 10, the core substrate 20, the upper-layer wiring 30, the lower-layer wiring 40, and the opening 50 are configured in a manner similar to the first embodiment. It is to be noted that the wiring layer 32 of the upper-layer wiring 30 is provided with the via electrodes 33 illustrated in FIG. 1, although they are not illustrated in FIG. 45.

For example, the opening 80 reaches the prepreg 31 of the upper-layer wiring 30. As will be described later, this opening 80 is formed by forming the exterior wiring short-circuit section 81 as a short-circuit section that short-circuits the first electrode layer 12 and the second electrode layer 13, and then cutting the exterior wiring short-circuit section 81 after mounting or packaging. Provision of the exterior wiring short-circuit section 81 makes it possible to suppress destruction of the dielectric film 11 caused by a static electricity. This destruction may occur in, for example, a process of mounting a component on a surface of the circuit board 1C, or a packaging process of attaching the circuit board 1C to another substrate, after formation of the circuit board 1C is completed (i.e. after the formation of the opening 50 in the first embodiment). For example, when the circuit board 1C is an interposer substrate mounted with an LSI, the exterior wiring short-circuit section 81 is allowed to be disconnected after the LSI is mounted.

It is to be noted that FIG. 45 illustrates the case in which the exterior wiring short-circuit section 81 is provided in the wiring layer 32 of the upper-layer wiring 30 (i.e., in the same layer as the via electrodes 33). However, it goes without saying that the exterior wiring short-circuit section 81 may be provided in a layer higher than the wiring layer 32.

The circuit board 1C may be manufactured as follows, for example.

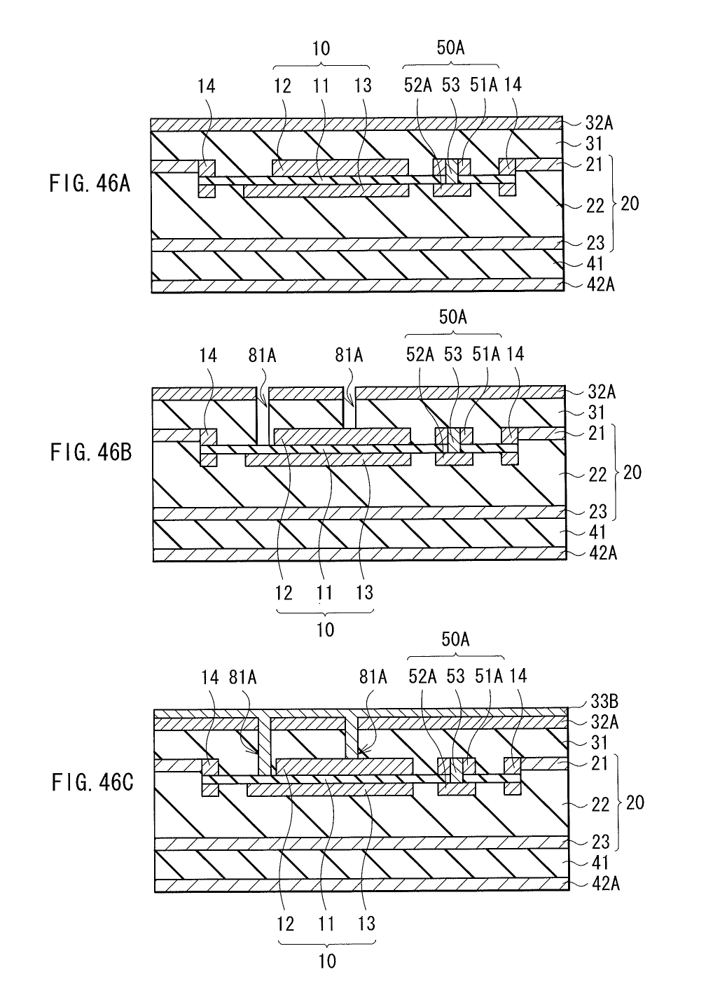

FIG. 46A to FIG. 48 illustrate a method of manufacturing a circuit board 1C in process order. It is to be noted that the same processes as those of the first embodiment will be described with reference to FIG. 2A to FIG. 9C. In the following, the case in which the exterior wiring short-circuit section 81 is provided in the wiring layer 32 of the upper-layer wiring 30 (i.e., in the same layer as the via electrodes 33) will be described.

First, in a manner similar to that of the first embodiment, a capacitive device material 10A in which the dielectric film 11 and the conductive film 13A are laminated in this order on the metallic foil 12A is prepared by the process illustrated in FIG. 2A. Next, in a manner similar to the first embodiment, a mask intended to process the conductive film 13A is formed on this conductive film 13A of the capacitive device material 10A, by using the dry film 61 or the like having an opening in a desired region, in the process illustrated in FIG. 2B. The conductive film 13A is then processed using, for example, a chemical, and the dry film 61 is removed, in the process illustrated in FIG. 2C, as in the case of the first embodiment. As a result, in a manner similar to that of the first embodiment, the second electrode layer 13 of the capacitive device 10, the second leading wiring 52 extended from the second electrode layer 13, and the land 52A provided at the tip of the second leading wiring 52 are formed as illustrated in FIG. 3.

It is to be noted that, although the case in which the conductive film 13A is patterned first is described here, the metallic foil 12A may be patterned first. When strength in subsequent handling is taken into consideration, it is desirable to pattern the conductive film 13A first.

Next, in a manner similar to that of the first embodiment, the copper foil 21A having an opening in a desired region, and the capacitive device material 10A matching the opening of the copper foil 21A, and the copper foil 23A are adhered to the prepreg 22 by a pressure press method or the like, in the processes illustrated in FIG. 4A and FIG. 4B. Here, an adhesion surface of the capacitive device material 10A is on the patterned conductive film 13A side, and the adhesion is performed by aligning the capacitive device material 10A with the opening of the copper foil 21A.

After the copper foil 21A and the copper foil 23A as well as the capacitive device material 10A are adhered to the prepreg 22, a mask intended to process the metallic foil 12A is formed on the metallic foil 12A of the capacitive device material 10A, by using a dry film 62 having an opening in a desired region, in the process illustrated in FIG. 5A, as in the case of the first embodiment. Next, in a manner similar to that of the first embodiment, the metallic foil 12A and the dielectric film 11 of the capacitive device material 10A are processed using, for example, a chemical, so that the opening section 53A is formed in the metallic foil 12A and the dielectric film 11, in the process illustrated in FIG. 5B. This opening section 53A is provided on the land 52A at the tip of the second leading wiring 52. Subsequently, in a manner similar to that of the first embodiment, a short-circuit electrode 53 is formed in the opening section 53A, in the process illustrated FIG. 5C. As a result, the second electrode layer 13 and the metallic foil 12A are short-circuited through the short-circuit electrode 53. Thus, even when a static electricity is stored in a subsequent process, a current is allowed to escape through the short-circuit electrode 53, which suppresses damage to the dielectric film 11.

After the short-circuit electrode 53 is formed, a mask intended to process the metallic foil 12A is formed on the metallic foil 12A of the capacitive device material 10A, by using a dry film 63 having an opening in a desired region, in the process illustrated in FIG. 6A, as in the case of the first embodiment. Subsequently, in a manner similar to that of the first embodiment, the metallic foil 12A and the copper foil 21A are processed using, for example, a chemical, and the dry film 63 is removed, in the process illustrated in FIG. 6B. As a result, the first electrode layer 12 of the capacitive device 10, the first leading wiring 51 extended from the first electrode layer 12, and the land 51A provided at the tip of the first leading wiring 51 are formed as illustrated in FIG. 7, in a manner similar to that of the first embodiment. Further, in this process, a mask (not illustrated) is similarly formed also on the copper foil 23A on a back side, so that the copper foil 23A is processed.

The first electrode layer 12 is formed at a position facing the second electrode layer 13, with the dielectric film 11 interposed therebetween. As a result, the capacitive device 10 which has the first electrode layer 12 and the second electrode layer 13 with the dielectric film 11 provided therebetween is formed.

The first leading wiring 51 is disposed at a position which does not overlap the second leading wiring 52 in the xy plane. This suppresses occurrence of parasitic capacitance between the first leading wiring 51 and the second leading wiring 52.

The land 51A provided at the tip of the first leading wiring 51 and the land 52A provided at the tip of the second leading wiring 52 are disposed at the respective positions overlapping in the xy plane, and short-circuited through the short-circuit electrode 53. As a result, the short-circuit section 50A that short-circuits the first electrode layer 12 and the second electrode layer 13 through the short-circuit electrode 53 is formed.

Further, the wiring layer 21 is formed by processing the copper foil 21A, and the wiring layer 23 is formed by processing the copper foil 23A. As a result, the core substrate 20 which includes the capacitive device 10, the wiring layers 21 and 23, and the prepreg 22 is formed by the process illustrated in FIG. 6B, in a manner similar to that of the first embodiment. Here, the first leading wiring 51 extended from the first electrode layer 12 and the second leading wiring 52 extended from the second electrode layer 13 are short-circuited through the short-circuit electrode 53 of the short-circuit section 50A. Therefore, even when a static electricity is stored, a current is allowed to escape through the short-circuit electrode 53, so that damage to the dielectric film 11 is suppressed.

Next, the prepreg 31 and the prepreg 41 as well as the copper foil 32A and the copper foil 42A are adhered to the core substrate 20, as illustrated in FIG. 46A. Subsequently, as illustrated in FIG. 46B, an opening section 81A for the exterior wiring short-circuit section 81 is formed in the copper foil 32A and the prepreg 31 by laser beam machining. Further, in the same process, the opening section 33A for the via electrodes 33 as illustrated in FIG. 8B are formed. Then, the via-electrode material film 33B is formed on a top surface of the copper foil 32A and inside the opening sections 33A and 81A, as illustrated in FIG. 46C.

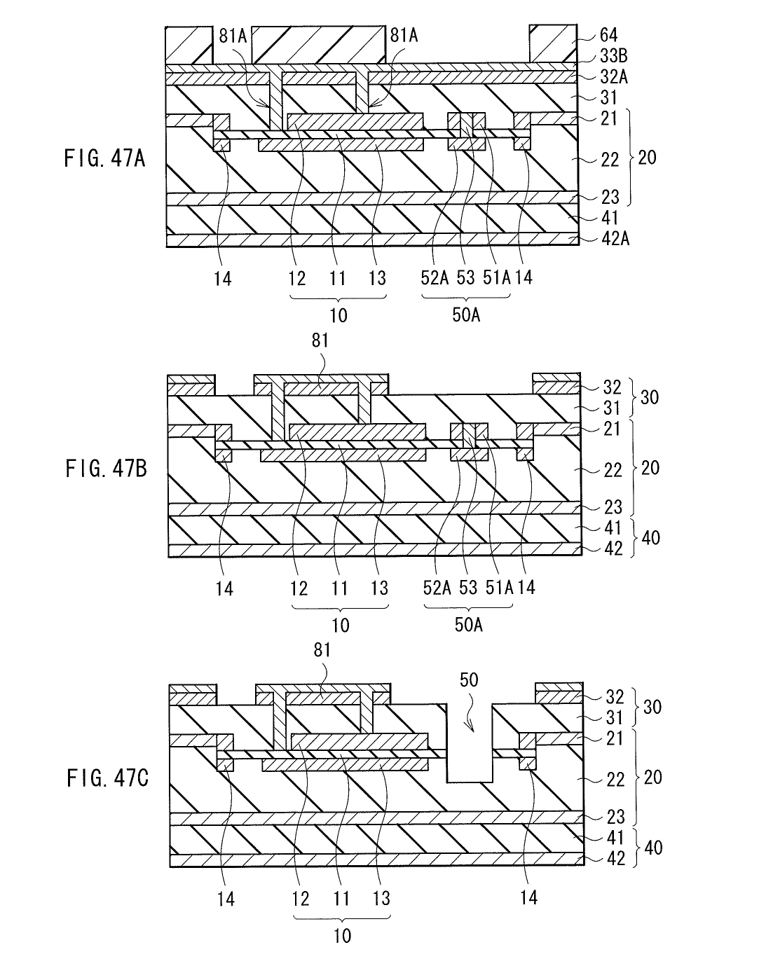

Subsequently, as illustrated in FIG. 47A, a mask intended to process the via-electrode material film 33B and the copper foil 32A is formed on the via-electrode material film 33B, by using the dry film 64 having an opening in a desired region. The via-electrode material film 33B and the copper foil 32A are then processed using, for example, a chemical, so that the wiring layer 32 and the exterior wiring short-circuit section 81 are formed, as illustrated in FIG. 47B. Further, in the same process, the via electrodes 33 illustrated in FIG. 9B are formed. As a result, the upper-layer wiring 30 made of the prepreg 31 and the wiring layer 32 is formed. The dry film 64 is removed.

Further, in this process, a mask (not illustrated) is formed also on the copper foil 42A on an underside and the copper foil 42A is processed so that the wiring layer 42 is formed. The lower-layer wiring 40 configured of the prepreg 41 and the wiring layer 42 is thereby formed.

After the formation of the upper-layer wiring 30 and the lower-layer wiring 40, the opening 50 is formed using a technique such as laser beam machining and drilling. The short-circuit section 50A configured of the lands 51A and 52A as well as the short-circuit electrode 53 is thereby removed, as illustrated in FIG. 47C. In this process, the exterior wiring short-circuit section 81 is not disconnected.

After the opening 50 is formed by removing the short-circuit section 50A, a process of mounting a component on the surface of the circuit board 1C or a packaging process of attaching the circuit board 1C to another substrate is performed. Here, the first electrode layer 12 and the second electrode layer 13 are short-circuited through the exterior wiring short-circuit section 81. Therefore, destruction of the dielectric film 11 caused by the static electricity, which may occur in the mounting process or the packaging process, is suppressed.

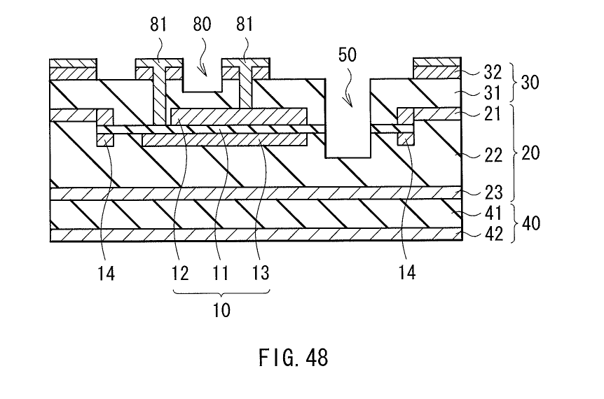

Upon completion of the mounting process or the packaging process, the opening 80 is formed by cutting the exterior wiring short-circuit section 81, as illustrated in FIG. 48.

It is to be noted that, although the openings 50 and 80 may be left as they are, it is desirable to seal the openings 50 and 80 using a solder resist or the like to increase the reliability further.

In this way, the exterior wiring short-circuit section 81 is provided in the present embodiment. Thus, the following advantage is provided in addition to the effects of the first embodiment. That is, it is possible to suppress the destruction of the dielectric film 11 caused by the static electricity, which may occur in, for example, the process of mounting the component on the surface of the circuit board 1C, or the packaging process of attaching the circuit board 1C to another substrate, after the formation of the circuit board 1C is completed (i.e. after the formation of the opening 50 in the first embodiment).

It is to be noted that, in the present embodiment, the case where the short-circuit section 50A is formed using the short-circuit electrode 53 of the first embodiment. However, the short-circuit section 50A may be formed using the damaged section 54 of the second embodiment or the contact section 55 of the third embodiment. Further, the short-circuit section 50A may be provided inside the first electrode layer 12 and the second electrode layer 13, in a manner similar to that of the fourth embodiment. Furthermore, the present embodiment is applicable to a case where the first capacitive device 70A and the second capacitive device 70B which are opposite in polarity are disposed in proximity to each other, and the routed wiring 56 is provided as the short-circuit section 50A as in the case of the fifth embodiment.

The disclosure has been described with reference to the embodiments, but is not limited thereto and may be variously modified. For example, each of the embodiments has been described specifically using the configuration of the circuit board as an example. However, it is not necessary to provide all the elements, and other elements may be provided additionally.

It is possible to achieve at least the following configurations from the above-described example embodiments of the disclosure.

(1) A method of manufacturing a circuit board, the method including:

forming a capacitive device and a short-circuit section with use of a capacitive device material including a dielectric film and a conductive film in this order on metallic foil, the capacitive device including a first electrode layer and a second electrode layer with the dielectric film interposed therebetween, and the short-circuit section short-circuiting the first electrode layer and the second electrode layer;

forming an upper-layer wiring above the capacitive device and the short-circuit section; and

removing or cutting the short-circuit section after the forming of the upper-layer wiring.

(2) The method of manufacturing a circuit board according to (1), wherein

the forming of the capacitive device and the short-circuit section includes

forming the second electrode layer by processing the conductive film,

providing an opening section in the dielectric film, and providing a short-circuit electrode in the opening section, and

forming the first electrode layer by processing the metallic foil, and forming the short-circuit section including the short-circuit electrode.

(3) The method of manufacturing a circuit board according to (1), wherein

the forming of the capacitive device and the short-circuit section includes

forming the second electrode layer by processing the conductive film,

forming a damaged section in the dielectric film by laser irradiation, and

forming the first electrode layer by processing the metallic foil, and forming the short-circuit section including the damaged section.

(4) The method of manufacturing a circuit board according to (1), wherein

the forming of the capacitive device and the short-circuit section includes

forming the conductive film on the dielectric film after providing an opening section in the dielectric film with use of a base material including the dielectric film on the metallic foil, and thereby forming the capacitive device material including a contact section in the opening section, the contact section establishing contact between the metallic foil and the conductive film,

forming the second electrode layer by processing the conductive film, and

forming the first electrode layer by processing the metallic foil, and forming the short-circuit section including the contact section.

(5) The method of manufacturing a circuit board according to any one of (2) to (4),
wherein

a first leading wiring is formed between the first electrode layer and the short-circuit section,

a second leading wiring is formed between the second electrode layer and the short-circuit section, and

the first leading wiring and the second leading wiring are arranged at respective positions that do not overlap in a plane orthogonal to a lamination direction of the first electrode layer, the dielectric film, and the second electrode layer.

(6) The method of manufacturing a circuit board according to any one of (2) to (5), wherein the short-circuit section is formed inside the first electrode layer and the second electrode layer.

(7) The method of manufacturing a circuit board according to (1), wherein

a first capacitive device and a second capacitive device are formed as the capacitive device, the first capacitive device including the first electrode layer on a top surface of the dielectric film and including the second electrode layer on an undersurface of the dielectric film, and the second capacitive device including the second electrode layer on the top surface of the dielectric film and including the first electrode layer on the undersurface of the dielectric film, and

a routed wiring is formed as the short-circuit section, the routed wiring connecting the first electrode layer of the first capacitive device and the second electrode layer of the second capacitive device.

(8) The method of manufacturing a circuit board according to any one of (1) to (7), wherein the short-circuit section is removed or cut using one of drilling, laser beam machining, and etching.
(9) The method of manufacturing a circuit board according to any one of (1) to (8), wherein, in the forming of the upper-layer wiring, an exterior wiring short-circuit section that short-circuits the first electrode layer and the second electrode layer through an exterior wiring is formed, and the exterior wiring short-circuit section is removed or cut after mounting or packaging.
(10) The method of manufacturing a circuit board according to any one of (1) to (9), wherein the dielectric film is configured using one of strontium titanate (SrTiO₃), barium titanate (BaTiO₃), barium strontium titanate, and lead zirconate titanate.

The disclosure contains subject related to that disclosed in Japanese Priority Patent Application JP 2011-271194 filed in the Japan Patent Office on Dec. 12, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A method of manufacturing a circuit board, the method comprising:
forming a capacitive device and a short-circuit section with use of a capacitive device material including a dielectric film and a conductive film in this order on metallic foil, the capacitive device including a first electrode layer and a second electrode layer with the dielectric film interposed therebetween, and the short-circuit section short-circuiting the first electrode layer and the second electrode layer;
forming an upper-layer wiring above the capacitive device and the short-circuit section; and
removing or cutting the short-circuit section after the forming of the upper-layer wiring.

2. The method of manufacturing a circuit board according to claim 1, wherein
the forming of the capacitive device and the short-circuit section includes
forming the second electrode layer by processing the conductive film,
providing an opening section in the dielectric film, and providing a short-circuit electrode in the opening section, and
forming the first electrode layer by processing the metallic foil, and forming the short-circuit section including the short-circuit electrode.

3. The method of manufacturing a circuit board according to claim 1, wherein
the forming of the capacitive device and the short-circuit section includes
forming the second electrode layer by processing the conductive film,
forming a damaged section in the dielectric film by laser irradiation, and
forming the first electrode layer by processing the metallic foil, and forming the short-circuit section including the damaged section.

4. The method of manufacturing a circuit board according to claim 1, wherein
the forming of the capacitive device and the short-circuit section includes
forming the conductive film on the dielectric film after providing an opening section in the dielectric film with use of a base material including the dielectric film on the metallic foil, and thereby forming the capacitive device material including a contact section in the opening section, the contact section establishing contact between the metallic foil and the conductive film,
forming the second electrode layer by processing the conductive film, and
forming the first electrode layer by processing the metallic foil, and forming the short-circuit section including the contact section.

5. The method of manufacturing a circuit board according to claim 2, wherein
a first leading wiring is formed between the first electrode layer and the short-circuit section,
a second leading wiring is formed between the second electrode layer and the short-circuit section, and
the first leading wiring and the second leading wiring are arranged at respective positions that do not overlap in a plane orthogonal to a lamination direction of the first electrode layer, the dielectric film, and the second electrode layer.

6. The method of manufacturing a circuit board according to claim 2, wherein the short-circuit section is formed inside the first electrode layer and the second electrode layer.

7. The method of manufacturing a circuit board according to claim 1, wherein
a first capacitive device and a second capacitive device are formed as the capacitive device, the first capacitive device including the first electrode layer on a top surface of the dielectric film and including the second electrode layer on an undersurface of the dielectric film, and the second capacitive device including the second electrode layer on the top surface of the dielectric film and including the first electrode layer on the undersurface of the dielectric film, and
a routed wiring is formed as the short-circuit section, the routed wiring connecting the first electrode layer of the first capacitive device and the second electrode layer of the second capacitive device.

8. The method of manufacturing a circuit board according to claim 1, wherein the short-circuit section is removed or cut using one of drilling, laser beam machining, and etching.

9. The method of manufacturing a circuit board according to claim 1, wherein, in the forming of the upper-layer wiring, an exterior wiring short-circuit section that short-circuits the first electrode layer and the second electrode layer through an exterior wiring is formed, and the exterior wiring short-circuit section is removed or cut after mounting or packaging.

10. The method of manufacturing a circuit board according to claim 1, wherein the dielectric film is configured using one of strontium titanate (SrTiO₃), barium titanate (BaTiO₃), barium strontium titanate, and lead zirconate titanate.
